(19) United States
(12) Patent Application Publication
(10) Pub. No.: US 2025/0180792 A1
(43) Pub. Date: Jun. 5, 2025

(54) LIGHT ABSORPTION ANISOTROPIC FILM, MANUFACTURING METHOD THEREOF, LAMINATE, AND IMAGE DISPLAY DEVICE

(71) Applicant: FUJIFILM Corporation, Tokyo (JP)

(72) Inventor: Toshikazu SUMI, Kanagawa (JP)

(73) Assignee: FUJIFILM Corporation, Tokyo (JP)

(21) Appl. No.: 19/052,886

(22) Filed: Feb. 13, 2025

Related U.S. Application Data
(63) Continuation of application No. PCT/JP2023/028390, filed on Aug. 3, 2023.

(30) Foreign Application Priority Data
Aug. 30, 2022 (JP) 2022-136960

(51) Int. Cl. G02B 5/22

(52) U.S. Cl. CPC G02B 5/22

(57) ABSTRACT

A light absorption anisotropic film used in a laminate and an image display device, exhibiting excellent black density and a manufacturing method thereof. The light absorption anisotropic film contains a dichroic substance and a liquid crystal compound, in which at least a part of the dichroic substance forms an arrangement structure, and in a cross section observed with a scanning transmission electron microscope, when an average value of lengths of major axes of arrangement structures observed in a region A from one surface to 150 nm in a film thickness direction is denoted by Ltop and an average value of lengths of major axes of arrangement structures in a region B from the other surface to 150 nm in the film thickness direction is denoted by Llow, at least one of the following expression Ltop≤35 nm (1-1) or expression Llow≤35 nm (1-2) is satisfied.

### CROSS-REFERENCE TO RELATED APPLICATIONS

This application is a Continuation of PCT International Application No. PCT/JP2023/028390 filed on Aug. 3, 2023, which was published under PCT Article 21(2) in Japanese, and which claims priority under 35 U.S.C. § 119(a) to Japanese Patent Application No. 2022-136960 filed on Aug. 30, 2022. The above applications are hereby expressly incorporated by reference, in their entirety, into the present application.

### BACKGROUND OF THE INVENTION

### 1. Field of the Invention

The present invention relates to a light absorption anisotropic film, a manufacturing method thereof, a laminate, and an image display device.

### 2. Description of the Related Art

A light absorption anisotropic film is used in a wide variety of applications. For example, since an organic electroluminescence (EL) display device has a structure using metal electrodes, external light may be reflected, resulting in problems of contrast reduction and reflected glare. Therefore, in the related art, a polarizing plate including the light absorption anisotropic film has been used in order to suppress the adverse effect of external light reflection.

For example, JP2020-023153A discloses a polarizing plate having a polarizing layer (light absorption anisotropic film) formed of a composition containing a dichroic coloring agent (dichroic substance) and a liquid crystal compound.

### SUMMARY OF THE INVENTION

On the other hand, in recent years, an organic EL display device is required to have excellent black density in a front direction in order to further improve an image quality. The expression “excellent black density” means that the tint of black color is suppressed in a case where the image display device is black-displayed.

In such a case, the present inventors produce an organic EL display device including the polarizing plate disclosed in JP2020-023153A and evaluate the black density thereof, and it is found that the black density is not necessarily satisfied at the level required in recent years.

Therefore, in view of the above circumstances, an object of the present invention is to provide a light absorption anisotropic film exhibiting excellent black density in a case of being used in an image display device, a manufacturing method thereof, and a laminate and an image display device, each of which includes the light absorption anisotropic film.

As a result of intensive studies on the above-described problems, the present inventors have found that the black density is improved by forming an arrangement structure of a dichroic substance in a film and reducing a size of the arrangement structure near a surface of the film, and have completed the present invention.

That is, the present inventors have found that the above-described objects can be achieved by the following configurations.

(1) Alight absorption anisotropic film comprising:
a dichroic substance; and
a liquid crystal compound,
in which at least a part of the dichroic substance forms an arrangement structure, and
in a cross section observed with a scanning transmission electron microscope, in a case where an average value of lengths of major axes of arrangement structures observed in a region A from one surface to 150 nm in a film thickness direction is denoted by Ltop and an average value of lengths of major axes of arrangement structures in a region B from the other surface to 150 nm in the film thickness direction is denoted by Llow, at least one of the following expression (1-1) or expression (1-2) is satisfied,

$$Ltop \leq 35 nm , \qquad ( 1 - 1 )$$

$$Llow \leq 35 nm . \qquad ( 1 - 2 )$$

(2) The light absorption anisotropic film according to (1),
in which, in the cross section observed with the scanning transmission electron microscope, in a case where an average value of lengths of major axes of arrangement structures in a region C of 150 nm from a center in the film thickness direction is denoted by Lmid, at least one of the following expression (2-1) or expression (2-2) is satisfied,

$$Ltop / Lmid < 0.87 , \qquad ( 2 - 1 )$$

$$Llow / Lmid < 0.87 . \qquad ( 2 - 2 )$$

(3) The light absorption anisotropic film according to (1),
in which, in the cross section observed with the scanning transmission electron microscope, in a case where an average value of lengths of major axes of arrangement structures in a region C of 150 nm from a center in the film thickness direction is denoted by Lmid, the following expression (3-1) is satisfied,

$$Lmid > 40 nm . \qquad ( 3 - 1 )$$

(4) The light absorption anisotropic film according to any one of (1) to (3), further comprising:
an unevenly distributed substance which is unevenly distributed in at least one of the region A or the region B.

(5) The light absorption anisotropic film according to (4),
in which a weight-average molecular weight of the unevenly distributed substance is 1000 or more.

(6) A manufacturing method of the light absorption anisotropic film according to any one of (1) to (5), the manufacturing method comprising:
a coating film-forming step of forming a coating film by applying a composition for forming a light absorption anisotropic film, containing a dichroic substance and a liquid crystal compound, onto an alignment film; and
an alignment step of aligning the dichroic substance contained in the coating film to obtain the light absorption anisotropic film.

(7) The manufacturing method according to (6),
in which the alignment step includes a step of exposing the coating film to light in an atmosphere.

(8) The manufacturing method according to (6) or (7),
in which the alignment step includes a step of exposing the coating film to ultraviolet rays which do not include light of 330 nm or more.

(9) A laminate comprising:
the light absorption anisotropic film according to any one of (1) to (5); and
a λ/4 plate.

(10) An image display device comprising:
the light absorption anisotropic film according to any one of (1) to (5).

As described below, according to the present invention, it is possible to provide a light absorption anisotropic film exhibiting excellent black density in a case of being used in an image display device, a manufacturing method thereof, and a laminate and an image display device, each of which includes the light absorption anisotropic film.

### BRIEF DESCRIPTION OF THE DRAWINGS

FIG. 1 is a schematic partial cross-sectional view of a light absorption anisotropic film 100 which is one aspect of a light absorption anisotropic film according to an embodiment of the present invention.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In the present specification, numerical ranges represented by “to” include numerical values before and after “to” as lower limit values and upper limit values.

In addition, in the present specification, parallel, orthogonal, horizontal, and vertical do not indicate parallel, orthogonal, horizontal, and vertical in a strict sense, but respectively indicate a range of parallel±10°, a range of orthogonal±10°, a range of horizontal±10°, and a range of vertical±10°.

In addition, in the present specification, substances corresponding to respective components may be used alone or in combination of two or more kinds thereof. Here, in a case where two or more kinds of substances corresponding to respective components are used in combination, the content of the components indicates the total content of the substances used in combination unless otherwise specified.

In addition, regarding a light absorption anisotropic film, the fact that the black density, the durability, the heat resistance, and the alignment degree are excellent is also referred to as “effects and the like of the present invention are excellent”.

In addition, in the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

### [1] Light Absorption Anisotropic Film

The light absorption anisotropic film according to the embodiment of the present invention (hereinafter, also referred to as “film according to the embodiment of the present invention”) contains a dichroic substance and a liquid crystal compound, in which at least a part of the dichroic substance forms an arrangement structure, and in a cross section observed with a scanning transmission electron microscope, in a case where an average value of lengths of major axes of arrangement structures observed in a region A from one surface to 150 nm in a film thickness direction is denoted by Ltop and an average value of lengths of major axes of arrangement structures in a region B from the other surface to 150 nm in the film thickness direction is denoted by Llow, at least one of the following expression (1-1) or expression (1-2) is satisfied.

$$Ltop \leq 35 nm \qquad ( 1 - 1 )$$

$$Llow \leq 35 nm \qquad ( 1 - 2 )$$

Since the film according to the embodiment of the present invention has such a configuration, it is considered that the above-described objects of the present invention can be achieved. The reason is not clear, but it is presumed that the film according to the embodiment of the present invention has a small size of the arrangement structure near the surface, and thus scattering is unlikely to occur in a case where external light is incident.

In the film according to the embodiment of the present invention, the dichroic substances, the liquid crystal compounds, and the dichroic substance and the liquid crystal compound may be bonded to each other by a crosslinkable group, a polymerizable group, or the like.

Hereinafter, first, the arrangement structure will be described, and then each component contained in the film will be described.

### [Arrangement Structure]

In the light absorption anisotropic film according to the embodiment of the present invention, at least a part of the above-described dichroic substance forms an arrangement structure.

Here, the arrangement structure refers to a state in which, in the light absorption anisotropic film, the dichroic substances are collected to form an aggregate and molecules of the dichroic substances are periodically arranged in the aggregate.

In addition, the arrangement structure may be composed of only the dichroic substance, or may be composed of the liquid crystal compound and the dichroic substance.

In addition, the arrangement structure may be composed of one kind of dichroic substance, or may be composed of a plurality of kinds of dichroic substances.

In addition, an arrangement structure composed of a certain kind of dichroic substance and an arrangement structure composed of another kind of dichroic substance may coexist in the light absorption anisotropic film.

In addition, in a case where the light absorption anisotropic film contains a plurality of kinds of dichroic substances, among the plurality of kinds of dichroic substances contained in the light absorption anisotropic film, all of the plurality of kinds of dichroic substances may form the arrangement structure, or some kinds of dichroic substances may form the arrangement structure.

### [Size of Arrangement Structure]

### [Region A, Region B, and Region C]

First, a region A, a region B, and a region C of the light absorption anisotropic film according to the embodiment of the present invention will be described.

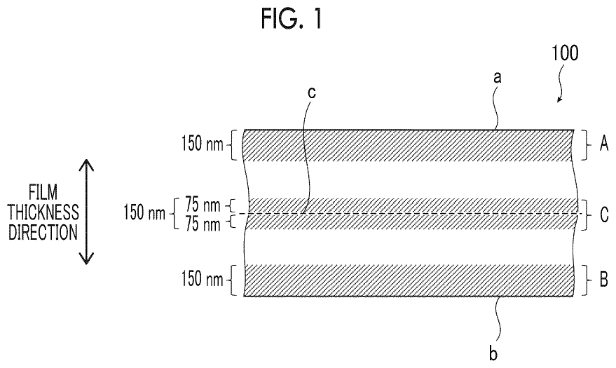

FIG. 1 is a schematic partial cross-sectional view of light absorption anisotropic film 100 which is one aspect of the light absorption anisotropic film according to the embodiment of the present invention.

As shown in FIG. 1, the region A is a region from one surface a to 150 nm in a film thickness direction. In addition, the region B is a region from the other surface b to 150 nm in the film thickness direction. In addition, the region C is a region of 150 nm from a center in the film thickness direction, in other words, a region consisting of a region from a center c in the film thickness direction to 75 nm in the film thickness direction (surface a) and a region from the center c in the film thickness direction to 75 nm in the film thickness direction (surface b).

In the present specification, in a case where the light absorption anisotropic film is produced by applying a composition for forming a light absorption anisotropic film, containing a dichroic substance and a liquid crystal compound, onto a base material (for example, an alignment film), a region on a coating surface side is referred to as the region A, and a region on a base material side is referred to as the region B.

### [Expression (1-1) and Expression (1-2)]

In a cross section of the film according to the embodiment of the present invention observed with a scanning transmission electron microscope, in a case where an average value of lengths L of major axes of arrangement structures observed in a region A from one surface to 150 nm in a film thickness direction is denoted by Ltop and an average value of lengths of major axes of arrangement structures in a region B from the other surface to 150 nm in the film thickness direction is denoted by Llow, at least one of the following expression (1-1) or expression (1-2) is satisfied.

$$Ltop \leq 35 nm \qquad ( 1 - 1 )$$

$$Llow \leq 35 nm \qquad ( 1 - 2 )$$

From the reason that the effects and the like of the present invention are more excellent, Ltop and Llow are each independently preferably 30 nm or less, and more preferably 25 nm or less.

The lower limit values of Ltop and Llow are not particularly limited, but from the reason that the effects and the like of the present invention are more excellent, the values are each independently preferably 5 nm or more, more preferably 7 nm or more, and still more preferably 10 nm or more.

### <Method>

### (Expression (1-1))

Examples of a method for allowing the light absorption anisotropic film to satisfy the expression (1-1) include a method of further adding a surfactant and a substance having high affinity with the surfactant (for example, a small Log P value (octanol/water partition coefficient)) and a high molecular weight (for example, Mw of 1,000 or more) to the composition for forming a light absorption anisotropic film in the manufacturing method according to the embodiment of the present invention (a coating film-forming step and an alignment step), which will be described later. In this case, in a coating film to be formed, the surfactant is unevenly distributed on the coating surface side, and accordingly, the above-described substance is also unevenly distributed in the region A on the coating surface side due to the affinity with the surfactant. That is, the above-described substance functions as an unevenly distributed substance which is unevenly distributed in the region A. In addition, the presence of the unevenly distributed substance having a high molecular weight in the region A increases a viscosity of the region A, and thus a formation rate of the arrangement structure of the dichroic substance in the region A decreases. As a result, a light absorption anisotropic film having a small size (Ltop) of the arrangement structure of the region A can be obtained. The value of Ltop can be further adjusted depending on the type, molecular weight, addition amount, and the like of the unevenly distributed substance.

Examples of another method for allowing the light absorption anisotropic film to satisfy the expression (1-1) include a method (suitable aspect 2) of exposing the coating film to short-wavelength UV, which will be described later.

### (Expression (1-2))

In addition, examples of a method for allowing the light absorption anisotropic film to satisfy the expression (1-2) include a method in which, in the manufacturing method according to the embodiment of the present invention described later, a substance having a small ASP value (difference in solubility parameter) and a high molecular weight (for example, Mw of 1,000 or more) with respect to a base material (for example, an alignment film) to which the composition is applied is further added to the composition for forming a light absorption anisotropic film. In this case, in a coating film to be formed, the above-described substance is unevenly distributed in the region B on a base material surface side due to the affinity with the base material. That is, the above-described substance functions as an unevenly distributed substance which is unevenly distributed in the region B. In addition, the presence of the unevenly distributed substance having a high molecular weight in the region B increases a viscosity of the region B, and thus a formation rate of the arrangement structure of the dichroic substance in the region B decreases. As a result, a light absorption anisotropic film having a small size (Llow) of the arrangement structure of the region B can be obtained. The value of Llow can be further adjusted depending on the type, molecular weight, addition amount, and the like of the unevenly distributed substance.

Examples of another method for allowing the light absorption anisotropic film to satisfy the expression (1-2) include a method (suitable aspect 1) of exposing the coating film to light in an atmosphere, which will be described later.

### [Expression (2-1) and Expression (2-2)]

From the reason that the effects and the like (particularly, durability and heat resistance) of the present invention are more excellent, in the cross section of the film according to the embodiment of the present invention observed with the scanning transmission electron microscope, in a case where an average value of lengths of major axes of arrangement structures in a region C of 150 nm from a center in the film thickness direction is denoted by Lmid, it is preferable that at least one of the following expression (2-1) or expression (2-2) is satisfied. The definitions of Ltop and Llow are as described above.

$$Ltop / Lmid < 0.87 \qquad ( 2 - 1 )$$

$$Llow / Lmid < 0.87 \qquad ( 2 - 2 )$$

From the reason that the effects and the like (particularly, durability and heat resistance) of the present invention are more excellent, Ltop/Lmid and Llow/Lmid are each independently preferably 0.70 or less, more preferably 0.60 or less, and still more preferably 0.50 or less; and the lower limit values of Ltop/Lmid and Llow/Lmid are not particularly limited, but from the reason that the effects and the like of the present invention are more excellent, the values are each independently preferably 0.10 or more, more preferably 0.20 or more, and still more preferably 0.30 or more.

### <Method>

Examples of a method for allowing the light absorption anisotropic film to satisfy the expression (2-1) or the expression (2-2) include the same method as the method for allowing the light absorption anisotropic film to satisfy the expression (1-1) or the expression (1-2) described above. That is, in a case where Ltop or Llow is relatively smaller than Lmid, alight absorption anisotropic film satisfying the expression (2-1) or the expression (2-2) is obtained.

### [Expression (3-1)]

From the reason that the effects and the like (particularly, durability and heat resistance) of the present invention are more excellent, it is preferable that the film according to the embodiment of the present invention satisfies the following expression (3-1). The definition of Lmid is as described above.

$$Lmid > 40 nm \qquad ( 3 - 1 )$$

From the reason that the effects and the like (particularly, durability and heat resistance) of the present invention are more excellent, Lmid is preferably 50 nm or more.

The upper limit of Lmid is not particularly limited, but from the reason that the effects and the like of the present invention are more excellent, it is preferably 100 nm or less, and more preferably 80 nm or less.

### <Method>

Examples of a method for allowing the light absorption anisotropic film to satisfy the expression (3-1) include the manufacturing method according to the embodiment of the present invention described later.

### [Observation of Cross Section]

Next, the observation of the cross section with a scanning transmission electron microscope will be described.

In the present invention, the cross section is observed with a scanning transmission electron microscope (hereinafter, also referred to as “STEM”) as follows.

First, an ultra-thin section of the light absorption anisotropic film, having a thickness of 100 nm in a film thickness direction, is produced by cutting the light absorption anisotropic film in the film thickness direction using an ultramicrotome.

Next, the ultra-thin section is placed on a grid with a carbon support film for STEM observation.

Thereafter, the grid is placed in the scanning transmission electron microscope, and the cross section is observed at an electron beam acceleration voltage of 30 kV.

### [Measurement of Length L of Major Axis]

In addition, the length L of the major axis of the arrangement structure is specifically measured as follows.

First, as described above, the cross section of the light absorption anisotropic film is observed with STEM, a captured image is analyzed to create a frequency histogram, and a frequency at which the frequency is maximized and a standard deviation of a frequency distribution are acquired. Next, a frequency at which the frequency is 1.3 times the standard deviation on a dark side from the frequency at which the frequency is maximized is set as a threshold value. Next, an image in which the brightness is binarized is created using the threshold value, the binarized dark region is approximated to an ellipse, and the length of the major axis of the approximated ellipse is set as the length L of the major axis of the arrangement structure.

The length L of the major axis of the arrangement structure may be measured using known image processing software. Examples of the image processing software include image processing software “ImageJ”.

For each region (region A, region B, and region C), the above-described image analysis is performed, and the arrangement structure satisfying L≥5 nm is extracted and counted in three randomly selected regions (total of 40 μm²) of 13.58 μm², which do not overlap with each other.

The counting of such an arrangement structure is performed in 10 randomly selected regions of 40 μm² (13.58 μm²×3), which do not overlap each other.

In addition, for each region, the average value of the lengths of the major axes of the arrangement structures at the 10 regions where the measurement is performed is calculated, and this average value is respectively denoted by Ltop (region A), Llow (region B), and Lmid (region C).

It is noted that the measurement is actually performed in a region of 13.58 μm²×3=40.74 μm², but in the present invention, the number of digits is rounded down and “per 40 μm²” is used for convenience.

### [Dichroic Substance]

The dichroic substance contained in the film according to the embodiment of the present invention is not particularly limited, and examples thereof include a visible light absorbing material (dichroic coloring agent), a light emitting material (such as a fluorescent material or a phosphorescent material), an ultraviolet absorbing material, an infrared absorbing material, a non-linear optical material, a carbon nanotube, and an inorganic material (for example, a quantum rod). In addition, known dichroic substances (dichroic coloring agents) of the related art can be used.

Examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] of JP2013-037353A, paragraphs [0049] to [0073] of JP2012-063387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] of WO2017/154695A, paragraphs [0013] to [0037] of WO2017/195833A, and paragraphs [0014] to [0034] of WO2018/164252A.

In the film according to the embodiment of the present invention, two or more kinds of dichroic substances may be used in combination. For example, from the viewpoint of making the color of the light absorption anisotropic film closer to black, it is preferable that at least one dichroic substance having a maximal absorption wavelength in a wavelength range of 370 nm or more and less than 500 nm and at least one dichroic substance having a maximal absorption wavelength in a wavelength range of 500 nm or more and less than 700 nm are used in combination.

The above-described dichroic substance may have a crosslinkable group.

Examples of the above-described crosslinkable group include a (meth)acryloyl group, an epoxy group, an oxetanyl group, and a styryl group; and among these, from the reason that the effects and the like of the present invention are more excellent, a (meth)acryloyl group is preferable.

### [Content]

In the film according to the embodiment of the present invention, from the reason that the effects and the like of the present invention are more excellent, a content of the dichroic substance is preferably 2 to 80 parts by mass, more preferably 10 to 60 parts by mass, and still more preferably 15 to 40 parts by mass with respect to 100 parts by mass of the liquid crystal compound described later.

In addition, in the film according to the embodiment of the present invention, from the reason that the effects and the like of the present invention are more excellent, the content of the dichroic substance is preferably 1% to 50% by mass, more preferably 5% to 40% by mass, and still more preferably 10% to 30% by mass.

### [Liquid Crystal Compound]

As the liquid crystal compound contained in the film according to the embodiment of the present invention, any of a high-molecular-weight liquid crystal compound or a low-molecular-weight liquid crystal compound can be used; and from the viewpoint of further increasing the alignment degree of the dichroic substance, a high-molecular-weight liquid crystal compound is preferably used.

Here, the “high-molecular-weight liquid crystal compound” refers to a liquid crystal compound having a repeating unit in the chemical structure.

In addition, the “low-molecular-weight liquid crystal compound” refers to a liquid crystal compound having no repeating unit in the chemical structure.

Examples of the high-molecular-weight liquid crystal compound include thermotropic liquid crystalline polymers described in JP2011-237513A and high-molecular-weight liquid crystal compounds described in paragraphs [0012] to [0042] of WO2018/199096A.

Examples of the low-molecular-weight liquid crystal compound include liquid crystal compounds described in paragraphs [0072] to [0088] of JP2013-228706A, and among these, a liquid crystal compound exhibiting smectic properties is preferable.

In addition, the high-molecular-weight liquid crystal compound and the low-molecular-weight liquid crystal compound may be used in combination as the liquid crystal compound.

In a case where the high-molecular-weight liquid crystal compound and the low-molecular-weight liquid crystal compound are used in combination, from the reason that the effects and the like of the present invention are more excellent, a proportion of the high-molecular-weight liquid crystal compound with respect to the entire liquid crystal compound is preferably 30% to 85% by mass, more preferably 45% to 80% by mass, and still more preferably 60% to 75% by mass.

### [Suitable Aspect]

From the viewpoint of further increasing the alignment degree of the dichroic substance, the liquid crystal compound is preferably a high-molecular-weight liquid crystal compound having a repeating unit represented by Formula (1) (hereinafter, also simply referred to as “repeating unit (1)”).

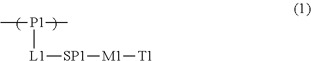

In Formula (1), P1 represents a main chain of the repeating unit, L1 represents a single bond or a divalent linking group, SP1 represents a spacer group, M1 represents a mesogen group, and T1 represents a terminal group.

Examples of the main chain of the repeating unit, represented by P1, include groups represented by Formulae (P1-A) to (P1-D); and among these, from the viewpoint of diversity and handleability of a monomer serving as a raw material, a group represented by Formula (P1-A) is preferable.

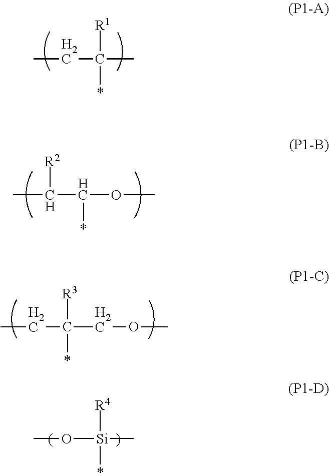

In Formulae (P1-A) to (P1-D), “*” represents a bonding position to L1 in Formula (1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The above-described alkyl group may be a linear or branched alkyl group, or an alkyl group having a cyclic structure (cycloalkyl group). In addition, the number of carbon atoms in the above-described alkyl group is preferably 1 to 5.

It is preferable that the group represented by Formula (P1-A) is one unit of a partial structure of poly(meth)acrylic acid ester, which is obtained by polymerization of (meth)acrylic acid ester.

It is preferable that the group represented by Formula (P1-B) is an ethylene glycol unit formed by ring-opening polymerization of an epoxy group of a compound having the epoxy group.

It is preferable that the group represented by Formula (P1-C) is a propylene glycol unit formed by ring-opening polymerization of an oxetane group of a compound having the oxetane group.

It is preferable that the group represented by Formula (P1-D) is a siloxane unit of a polysiloxane obtained by polycondensation of a compound having at least one of an alkoxysilyl group or a silanol group. Here, examples of the compound having at least one of an alkoxysilyl group or a silanol group include a compound having a group represented by Formula: SiR⁴(OR⁵)₂—. In the formula, R⁴ has the same definition as that for R⁴ in Formula (P1-D), and a plurality of R⁵'s each independently represent a hydrogen atom or an alkyl group having 1 to 10 carbon atoms.

In Formula (1), L1 represents a single bond or a divalent linking group.

Examples of the divalent linking group represented by L1 include —C(O)O—, —O—, —S—, —C(O)NR⁶—, —SO₂—, and —NR⁶R⁷—. In the formulae, R⁶ and R⁷ each independently represent a hydrogen atom or an alkyl group having 1 to 6 carbon atoms, which may have a substituent. In a case where P1 is a group represented by Formula (P1-A), from the viewpoint of further increasing the alignment degree of the dichroic substance, it is preferable that L1 is a group represented by —C(O)O—.

In a case where P1 is a group represented by any one of Formulae (P1-B) to (P1-D), from the viewpoint of further increasing the alignment degree of the dichroic substance, it is preferable that L1 is a single bond.

In Formula (1), from the viewpoint of easily expressing liquid crystallinity and availability of raw materials, it is preferable that the spacer group represented by SP1 has at least one structure selected from the group consisting of an oxyethylene structure, an oxypropylene structure, a polysiloxane structure, and an alkylene fluoride structure.

Here, the oxyethylene structure represented by SP1 is preferably a group represented by *—(CH₂—CH₂O)ₙ₁—* is preferable. In the formula, n1 represents an integer of 1 to 20, and * represents a bonding position to L1 or M1 in Formula (1). From the viewpoint of further increasing the alignment degree of the dichroic substance, n1 is preferably an integer of 2 to 10, more preferably an integer of 2 to 4, and most preferably 3.

In addition, from the viewpoint of further increasing the alignment degree of the dichroic substance, the oxypropylene structure represented by SP1 is preferably a group represented by *—(CH(CH₃)—CH₂O)ₙ₂—*. In the formula, n2 represents an integer of 1 to 3, and * represents a bonding position to L1 or M1.

In addition, from the viewpoint of further increasing the alignment degree of the dichroic substance, the polysiloxane structure represented by SP1 is preferably a group represented by *—(Si(CH₃)₂—O)₃—*. In the formula, n3 represents an integer of 6 to 10, and * represents a bonding position to L1 or M1.

In addition, from the viewpoint of further increasing the alignment degree of the dichroic substance, the alkylene fluoride structure represented by SP1 is preferably a group represented by *—(CF₂—CF₂)ₙ₄—*. In the formula, n4 represents an integer of 6 to 10, and * represents a bonding position to L1 or M1.

The mesogen group represented by M1 in Formula (1) is a group representing a main skeleton of a liquid crystal molecule which contributes to liquid crystal formation. A liquid crystal molecule exhibits liquid crystallinity which is in an intermediate state (mesophase) between a crystal state and an isotropic liquid state. The mesogen group is not particularly limited, and reference can be made to, for example, the description on pages 7 to 16 of “Flussige Kristalle in Tabellen II” (VEB Deutsche Verlag fur Grundstoff Industrie, Leipzig, 1984) and the description in Chapter 3 of “Lquid Crystal Handbook” (Maruzen, 2000) edited by Liquid Crystals Handbook Editing Committee.

As the mesogen group, for example, a group having at least one cyclic structure selected from the group consisting of an aromatic hydrocarbon group, a heterocyclic group, and an alicyclic group is preferable.

From the viewpoint of further increasing the alignment degree of the dichroic substance, the mesogen group preferably has an aromatic hydrocarbon group, more preferably has two to four aromatic hydrocarbon groups, and still more preferably has three aromatic hydrocarbon groups.

As the mesogen group, from the viewpoint of exhibiting the liquid crystallinity, of adjusting the liquid crystal phase transition temperature, of availability of raw materials, and of synthetic suitability, and from the viewpoint of further increasing the alignment degree of the dichroic substance, a group represented by Formula (M1-A) or Formula (M1-B) is preferable, and a group represented by Formula (M1-B) is more preferable.

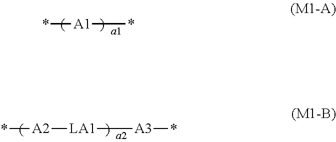

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent.

It is preferable that the divalent group represented by A1 is a 4- to 6-membered ring. In addition, the divalent group represented by A1 may be a monocyclic ring or a fused ring.
* represents a bonding position with respect to SP1 or T1.

Examples of the divalent aromatic hydrocarbon group represented by A1 include a phenylene group, a naphthylene group, a fluorene-diyl group, an anthracene-diyl group, and a tetracene-diyl group. From the viewpoint of design diversity of the mesogenic skeleton and the availability of raw materials, a phenylene group or a naphthylene group is preferable and a phenylene group is more preferable.

The divalent heterocyclic group represented by A1 may be any of aromatic or non-aromatic; but from the viewpoint of further increasing the alignment degree of the dichroic substance, a divalent aromatic heterocyclic group is preferable.

Examples of atoms other than carbon, constituting the divalent aromatic heterocyclic group, include a nitrogen atom, a sulfur atom, and an oxygen atom. In a case where the aromatic heterocyclic group has a plurality of atoms other than carbon, constituting a ring, these atoms may be the same or different from each other.

Examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Examples of the divalent alicyclic group represented by A1 include a cyclopentylene group and a cyclohexylene group.

In Formula (M1-A), a1 represents an integer of 1 to 10. In a case where a1 represents 2 or more, a plurality of A1's may be the same or different from each other.

In Formula (M1-B), A2 and A3 each independently represent a divalent group selected from the group consisting of an aromatic hydrocarbon group, a heterocyclic group, and an alicyclic group. Specific examples and suitable aspects of A2 and A3 are the same as those for A1 in Formula (M1-A), and thus the description thereof will not be repeated.

In Formula (M1-B), a2 represents an integer of 1 to 10, and in a case where a2 is 2 or more, a plurality of A2's may be the same or different from each other, a plurality of A3's may be the same or different from each other, and a plurality of LA1's may be the same or different from each other. From the viewpoint of further increasing the alignment degree of the dichroic substance, a2 is preferably an integer of 2 or more and more preferably 2.

In Formula (M1-B), in a case where a2 is 1, LA1 represents a divalent linking group. In a case where a2 is 2 or more, a plurality of LA1's each independently represent a single bond or a divalent linking group, and at least one of the plurality of LA1's is a divalent linking group. In a case where a2 is 2, from the viewpoint of further increasing the alignment degree of the dichroic substance, it is preferable that one of two LA1's is a divalent linking group and the other is a single bond.

Examples of the divalent linking group represented by LA1 in Formula (M1-B) include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)=N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)=N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)=N—N═C(Z′)—(Z, Z′, and Z″ each independently represent a hydrogen atom, a C₁ to C₄ alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among these, from the viewpoint of further increasing the alignment degree of the dichroic substance, —C(O)O— is preferable. LA1 may be a group obtained by combining two or more of these groups.

In Formula (1), examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—; R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, and a (meth)acryloyloxy group-containing group. Examples of the above-described (meth)acryloyloxy group-containing group include a group represented by -L-A (L represents a single bond or a linking group; specific examples of the linking group are the same as those for L1 and SP1 described above; A represents a (meth)acryloyloxy group).

From the viewpoint of further increasing the alignment degree of the dichroic substance, T1 is preferably an alkoxy group having 1 to 10 carbon atoms, more preferably an alkoxy group having 1 to 5 carbon atoms, and still more preferably a methoxy group.

These terminal groups may be further substituted with the groups or polymerizable groups described in JP2010-244038A.

From the viewpoint of further improving adhesiveness between a polarizer (light absorption anisotropic film) and an optically anisotropic layer and improving a cohesive force as a film, T1 is preferably a polymerizable group.

As the polymerizable group, a radically polymerizable group or a cationically polymerizable group is preferable.

As the radically polymerizable group, a generally known radically polymerizable group can be used, and an acryloyl group or a methacryloyl group is preferable. In this case, it is known that an acryloyl group generally has a high polymerization rate, and from the viewpoint of improving productivity, an acryloyl group is preferable; but a methacryloyl group can also be used as the polymerizable group.

As the cationically polymerizable group, a generally known cationically polymerizable group can be used, and examples thereof include an alicyclic ether group, a cyclic acetal group, a cyclic lactone group, a cyclic thioether group, a spiroorthoester group, and a vinyloxy group. Among these, an alicyclic ether group or a vinyloxy group is preferable, and an epoxy group, an oxetanyl group, or a vinyloxy group is more preferable.

### <Molecular Weight>

A weight-average molecular weight (Mw) of the high-molecular-weight liquid crystal compound having the repeating unit represented by Formula (1) described above is preferably 1,000 to 500,000 and more preferably 2,000 to 300,000. In a case where the Mw of the high-molecular-weight liquid crystal compound is within the above-described range, the high-molecular-weight liquid crystal compound is easily handled.

In particular, from the viewpoint of suppressing cracking during coating, the weight-average molecular weight (Mw) of the high-molecular-weight liquid crystal compound is preferably 10,000 or more and more preferably 10,000 to 300,000.

In addition, from the viewpoint of temperature latitude of the alignment degree, the weight-average molecular weight (Mw) of the high-molecular-weight liquid crystal compound is preferably less than 10,000 and more preferably 2,000 or more and less than 10,000.

In the present specification, the weight-average molecular weight (Mw) and the number-average molecular weight (Mn) are values measured by a gel permeation chromatography (GPC) method.
Solvent (eluent): N-methylpyrrolidone
Device name: TOSOH HLC-8220GPC
Column: using three columns of TOSOH TSKgel Super AWM-H (6 mm×15 cm) connected
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used

### [Content]

In the film according to the embodiment of the present invention, from the reason that the effects and the like of the present invention are more excellent, a content of the liquid crystal compound is preferably 50% by mass or more, and more preferably 70% by mass or more. The upper limit of the content of the liquid crystal compound is not particularly limited, but from the reason that the effects and the like of the present invention are more excellent, it is preferably 95% by mass or less.

### [Other Components]

The film according to the embodiment of the present invention may contain other components in addition to the above-described dichroic substance and liquid crystal compound. Examples of such other components include an unevenly distributed substance, a polymerization initiator, and a surfactant.

### [Unevenly Distributed Substance]

From the reason that Ltop or Llow is smaller and the effects and the like of the present invention are more excellent, one of preferred aspects of the film according to the embodiment of the present invention is a film containing an unevenly distributed substance which is unevenly distributed in at least one of the region A or the region B. The unevenly distributed substance may be present in a region (for example, the region C) other than the region A and the region B. Specific examples and suitable aspects of the unevenly distributed substance will be described later.

### <Content>

In the film according to the embodiment of the present invention, from the reason that Ltop or Llow is smaller and the effects and the like of the present invention are more excellent, a content of the unevenly distributed substance is preferably 0.5% by mass or more, more preferably 1.0% by mass or more, and still more preferably 1.5% by mass or more. In the film according to the embodiment of the present invention, from the reason that the effects and the like of the present invention are more excellent, the content of the unevenly distributed substance is preferably 3.0% by mass or less, and more preferably 2.5% by mass or less.

### [Thickness]

A thickness of the light absorption anisotropic film is not particularly limited, but from the reason that the effects and the like of the present invention are more excellent, it is preferably 300 to 8,000 nm, more preferably 450 to 5,000 nm, and still more preferably 1,000 to 3,000 nm.

The thickness of the light absorption anisotropic film is intended to be an average thickness of the light absorption anisotropic film. The above-described average thickness is obtained by measuring thicknesses of the light absorption anisotropic film at any five or more points and arithmetically averaging the measured values.

### [2] Manufacturing Method of Light Absorption Anisotropic Film

A method for manufacturing the above-described light absorption anisotropic film according to the embodiment of the present invention is not particularly limited, but from the reason that the effects and the like of the present invention are more excellent, a manufacturing method including the following steps (hereinafter, also referred to as “manufacturing method according to the embodiment of the present invention”) is preferable. Hereinafter, the fact that the obtained light absorption anisotropic film is excellent in the effects and the like of the present invention will also be simply referred to as “effects and the like of the present invention are excellent”.

### (1) Coating Film-Forming Step

A step of applying a composition for forming a light absorption anisotropic film, which contains a dichroic substance and a liquid crystal compound, onto an alignment film to form a coating film

### (2) Alignment Step

A step of aligning the dichroic substance contained in the above-described coating film to obtain a light absorption anisotropic film

Hereinafter, the respective steps will be described.

### [Coating Film-Forming Step]

The coating film-forming step is a step of applying a composition for forming a light absorption anisotropic film, which contains a dichroic substance and a liquid crystal compound, onto an alignment film to form a coating film.

The composition for forming a light absorption anisotropic film can be easily applied onto the alignment film by using a composition for forming a light absorption anisotropic film, which contains a solvent, or using a liquid such as a melt obtained by heating the composition for forming a light absorption anisotropic film.

Examples of the method of applying the composition for forming a light absorption anisotropic film include known methods such as a roll coating method, a gravure printing method, a spin coating method, a wire bar coating method, an extrusion coating method, a direct gravure coating method, a reverse gravure coating method, a die-coating method, a spraying method, and an ink jet method.

### [Composition for Forming Light Absorption Anisotropic Film]

The composition for forming a light absorption anisotropic film used in the coating film-forming step is a composition containing a dichroic substance and a liquid crystal compound (hereinafter, also referred to as “composition according to the present invention”).

The composition according to the present invention may contain other components in addition to the dichroic substance and the liquid crystal compound. Examples of such other components include an unevenly distributed substance, a polymerization initiator, a surfactant, and a solvent.

### <Dichroic Substance>

The composition according to the present invention contains a dichroic substance. Specific examples and suitable aspects of the dichroic substance are as described above.

### (Content)

In the composition according to the present invention, from the reason that the effects and the like of the present invention are more excellent, a content of the dichroic substance is preferably 2 to 80 parts by mass, more preferably 10 to 60 parts by mass, and still more preferably 20 to 40 parts by mass with respect to 100 parts by mass of the liquid crystal compound described later.

In addition, in the composition according to the present invention, from the reason that the effects and the like of the present invention are more excellent, the content of the dichroic substance in the total solid content is preferably 1% to 50% by mass, more preferably 10% to 40% by mass, and still more preferably 15% to 30% by mass.

In the present specification, the “solid content” refers to components in the composition excluding the solvent, and specific examples of the solid content include the liquid crystal compound, the dichroic substance, the unevenly distributed substance, the polymerization initiator, and the surfactant.

### <Liquid Crystal Compound>

The composition according to the present invention contains a liquid crystal compound. Specific examples and suitable aspects of the liquid crystal compound are as described above.

### (Content)

In the composition according to the present invention, from the reason that the effects and the like of the present invention are more excellent, a content of the liquid crystal compound in the total solid content is preferably 50% by mass or more, and more preferably 70% by mass or more. The upper limit of the content of the liquid crystal compound is not particularly limited, but from the reason that the effects and the like of the present invention are more excellent, it is preferably 95% by mass or less in the total solid content.

### <Unevenly Distributed Substance>

From the reason that Ltop or Llow is smaller and the effects and the like of the present invention are more excellent, one of preferred aspects of the composition according to the present invention is a composition containing an unevenly distributed substance.

From the viewpoint of sufficiently increasing a viscosity of a region in which the unevenly distributed substance is unevenly distributed in the coating film and improving phase separation properties, the unevenly distributed substance is preferably a polymer, and a weight-average molecular weight (Mw) thereof is preferably 1,000 or more and more preferably 5,000 or more.

The upper limit of Mw of the unevenly distributed substance is not particularly limited, but from the reason that the effects and the like of the present invention are more excellent, it is preferably 10,000,000 or less and more preferably 1,000,000 or less.

From the viewpoint of aligning properties, it is preferable that the unevenly distributed substance does not include a low surface energy structure (for example, a fluorine atom or a siloxane structure), which is included in a general surfactant.

Specific examples of the unevenly distributed substance include polyalkylene oxide (particularly, polyethylene oxide) and an epoxy resin (particularly, a cresol novolac-type epoxy resin).

### (Content)

In a case where the composition according to the present invention contains the unevenly distributed substance, from the viewpoint of sufficiently increasing a viscosity of a region in which the unevenly distributed substance is unevenly distributed in the coating film, a content of the unevenly distributed substance in the total solid content is preferably 0.5% by mass or more, more preferably 1.0% by mass or more, and still more preferably 1.5% by mass or more.

In the composition according to the present invention, from the reason that the effects and the like of the present invention are more excellent, the content of the unevenly distributed substance in the total solid content is preferably 3.0% by mass or less, and more preferably 2.5% by mass or less.

### <Polymerization Initiator>

From the reason that the effects and the like of the present invention are more excellent, the composition according to the present invention preferably contains a polymerization initiator. The polymerization initiator is not particularly limited, but from the reason that the effects and the like of the present invention are more excellent, a compound having photosensitivity, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds ([0065] of JP2016-027384A), and acylphosphine oxide compounds (JP1988-040799B (JP-S63-040799B), JP1993-029234B (JP-H5-029234B), JP1998-095788A (JP-H10-095788A), and JP1998-029997A (JP-H10-029997A)).

### (Content)

In a case where the composition according to the present invention contains the polymerization initiator, from the reason that the effects and the like of the present invention are more excellent, a content of the polymerization initiator is preferably 0.01 to 30 parts by mass and more preferably 0.1 to 15 parts by mass with respect to 100 parts by mass of the total amount of the dichroic substance and the liquid crystal compound.

### <Surfactant>

From the reason that the effects and the like of the present invention are more excellent, the composition according to the present invention preferably contains a surfactant.

In a case where the composition contains a surfactant, smoothness of a coated surface is improved, the alignment degree is further improved, and cissing and unevenness are suppressed so that in-plane uniformity is expected to be improved.

As the surfactant, from the reason that the effects and the like of the present invention are more excellent, a surfactant which allows the dichroic substance and the liquid crystal compound to be horizontally aligned on the coated surface side is preferable, and examples thereof include compounds described in paragraphs [0155] to [0170] of WO2016/009648A and compounds (horizontal alignment agents) described in paragraphs [0253] to [0293] of JP2011-237513A.

### (Content)

In a case where the composition according to the present invention contains the surfactant, a content of the surfactant is preferably 0.001 to 5 parts by mass and more preferably 0.01 to 3 parts by mass with respect to 100 parts by mass of the total amount of the dichroic substance and the liquid crystal compound.

### <Solvent>

From the viewpoint of workability, the composition according to the present invention preferably contains a solvent.

Examples of the solvent include organic solvents such as ketones, ethers, aliphatic hydrocarbons, alicyclic hydrocarbons, aromatic hydrocarbons, carbon halides, esters, alcohols, cellosolves, cellosolve acetates, sulfoxides, amides, and heterocyclic compounds, and water. These solvents may be used alone or in combination of two or more kinds thereof.

### (Content)

In a case where the composition according to the present invention contains the solvent, from the reason that the effects and the like of the present invention are more excellent, a content of the solvent is preferably 80% to 99% by mass, and more preferably 83% to 97% by mass with respect to the total mass of the composition.

### [Alignment Film]

The alignment film may be any film as long as it is a film which aligns (for example, horizontally aligns) the liquid crystal compound contained in the composition according to the present invention.

The alignment film can be provided by methods such as rubbing treatment of an organic compound (preferably a polymer) on a film surface, oblique vapor deposition of an inorganic compound, formation of a layer having microgrooves, or accumulation of an organic compound (for example, o-tricosanoic acid, dioctadecylmethylammonium chloride, or methyl stearate) by the Langmuir-Blodgett method (LB film). Furthermore, an alignment film in which an alignment function is generated by application of an electric field, application of a magnetic field, or irradiation with light has also been known. Among these, in the present invention, an alignment film formed by performing a rubbing treatment is preferable from the viewpoint of easily controlling a pretilt angle of the alignment film, and a photo-alignment film formed by irradiation with light is also preferable from the viewpoint of the uniformity of alignment.

### (1) Rubbing-Treated Alignment Film

A polymer material used for the alignment film formed by performing a rubbing treatment is described in a plurality of documents, and a plurality of commercially available products can be used. In the present invention, polyvinyl alcohol or polyimide, or derivatives thereof are preferably used. The alignment film can refer to the description on page 43, line 24 to page 49, line 8 of WO2001/88574A1.

A thickness of the alignment film is preferably 0.01 to 10 μm and more preferably 0.01 to 1 μm.

### (2) Photo-Alignment Film

A photo-alignment material used for the alignment film formed by irradiation with light is described in a plurality of documents. In the present invention, preferred examples thereof include azo compounds described in JP2006-285197A, JP2007-76839A, JP2007-138138A, JP2007-094071A, JP2007-121721A, JP2007-140465A, JP2007-156439A, JP2007-133184A, JP2009-109831A, JP3883848B, and JP4151746B; aromatic ester compounds described in JP2002-229039A; maleimide and/or alkenyl-substituted nadimide compounds having a photo-alignment unit, described in JP2002-265541A and JP2002-317013A; photo-crosslinkable silane derivatives described in JP4205195B and JP4205198B; and photo-crosslinkable polyimides, polyamides, or esters described in JP2003-520878A, JP2004-529220A, and JP4162850B. Azo compounds, photo-crosslinkable polyimides, polyamides, or esters are more preferable.

Among these, a photosensitive compound having a photoreactive group, which undergoes at least one of dimerization or isomerization by action of light is preferably used as the photo-alignment compound.

In addition, examples of the photoreactive group include a group having a cinnamic acid (cinnamoyl) structure (skeleton), a group having a coumarin structure (skeleton), a group having a chalcone structure (skeleton), a group having a benzophenone structure (skeleton), and a group having an anthracene structure (skeleton). Among these groups, a group having a cinnamoyl structure or a group having a coumarin structure is preferable, and a group having a cinnamoyl structure is more preferable.

In addition, the photosensitive compound having the above-described photo-aligned group may further have a crosslinkable group.

As the crosslinkable group, a thermally crosslinking group which causes a curing reaction due to action of heat or a photo-crosslinkable group which causes a curing reaction due to action of light is preferable, and the crosslinkable group may be a crosslinkable group which has both the thermally crosslinking group and the photo-crosslinkable group.

Examples of the above-described crosslinkable group include at least one selected from the group consisting of an epoxy group, an oxetanyl group, a group represented by —NH—CH₂—O—R (R represents a hydrogen atom or an alkyl group having 1 to 20 carbon atoms), a group having an ethylenically unsaturated double bond, and a blocked isocyanate group. Among these, an epoxy group, an oxetanyl group, or a group having an ethylenically unsaturated double bond is preferable.

A 3-membered cyclic ether group is also referred to as the epoxy group, and a 4-membered cyclic ether group is also referred to as the oxetanyl group.

In addition, specific examples of the group having an ethylenically unsaturated double bond include a vinyl group, an allyl group, a styryl group, an acryloyl group, and a methacryloyl group; and among these, an acryloyl group or a methacryloyl group is preferable.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photo-reaction in the photo-alignment material. A wavelength of the light to be used varies depending on the photo-alignment material to be used, and is not particularly limited as long as the wavelength is required for the photo-reaction. A peak wavelength of the light to be used for irradiation with light is preferably 200 nm to 700 nm, and ultraviolet light having a peak wavelength of 400 nm or less is more preferable.

Examples of a light source used for the light irradiation include commonly used light sources, for example, lamps such as a tungsten lamp, a halogen lamp, a xenon lamp, a xenon flash lamp, a mercury lamp, a mercury xenon lamp, or a carbon arc lamp, various lasers [for example, a semiconductor laser, a helium neon laser, an argon ion laser, a helium cadmium laser, and a yttrium aluminum garnet (YAG) laser], a light emitting diode, and a cathode ray tube.

As a method of obtaining the linearly polarized light, a method of using a polarizing plate (for example, iodine polarizing plate, dichroic substance polarizing plate, and wire grid polarizing plate), a method of using a prismatic element (for example, Glan-Thomson prism) or a reflective type polarizer using Brewster's angle, or a method of using light emitted from a polarized laser light source can be adopted. In addition, by using a filter, a wavelength conversion element, or the like, only light having a required wavelength may be radiated selectively.

In a case where light to be applied is the linearly polarized light, a method of applying light vertically or obliquely to the upper surface of the alignment film or the surface of the alignment film from the rear surface is employed. An incidence angle of light varies depending on the photo-alignment material, but is preferably 0° to 90° (vertical) and more preferably 40° to 90°.

In a case where the light to be applied is the non-polarized light, the alignment film is irradiated with the non-polarized light obliquely. An incidence angle is preferably 10° to 80°, more preferably 20° to 60°, and particularly preferably 300 to 50°.

The irradiation time is preferably 1 minute to 60 minutes and more preferably 1 minute to 10 minutes.

In a case where patterning is required, a method of performing irradiation with light using a photomask as many times as necessary for pattern preparation or a method of writing a pattern by laser light scanning can be employed.

### [Alignment Step]

The alignment step is a step of aligning the dichroic substance contained in the coating film. In this manner, the light absorption anisotropic film according to the embodiment of the present invention is obtained. In the alignment step, the dichroic substance is considered to be aligned along the liquid crystal compound aligned by the alignment film.

The alignment step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the dichroic substance contained in the composition for forming a light absorption anisotropic film may be aligned by the coating film-forming step or the drying treatment described above. For example, in an aspect in which the composition for forming a light absorption anisotropic film is prepared as a coating liquid containing a solvent, the light absorption anisotropic film according to the embodiment of the present invention may be obtained by drying the coating film and removing the solvent from the coating film so that the dichroic substance contained in the coating film is aligned.

It is preferable that the alignment step includes a heat treatment. As a result, the dichroic substance contained in the coating film is further aligned, and the alignment degree of the obtained light absorption anisotropic film is further increased.

From the viewpoint of manufacturing suitability, a heating temperature is preferably 10° C. to 250° C. and more preferably 25° C. to 190° C. In addition, the heating time is preferably 1 to 300 seconds and more preferably 1 to 60 seconds.

The heating treatment is preferably performed in multiple stages with different heating temperatures, and it is more preferable that, after performing a first stage heating treatment (for example, 140° C., 10 seconds), the heating treatment is performed at a temperature lower than the temperature of the first stage heating treatment (for example, a temperature lower than 40° C. to 90° C.) after cooling to a room temperature (20° C. to 25° C.), and the second stage or subsequent heating treatment (for example, 50° C. to 100° C., 15 seconds) is performed.

It is presumed that the dichroic substance is in a nematic alignment state (arrangement structure which is present unintentionally is melted) by the first stage heating treatment, and then a desired arrangement structure of the dichroic substance is formed by the second stage heating treatment.

The alignment step may include a cooling treatment performed after the heat treatment. The cooling treatment is a treatment of cooling the heated coating film to room temperature (20° C. to 25° C.). As a result, the alignment of the dichroic substance contained in the coating film is further fixed, and the alignment degree of the light absorption anisotropic film is further increased. A cooling unit is not particularly limited, and the cooling treatment can be performed according to a known method.

The light absorption anisotropic film according to the embodiment of the present invention can be obtained by performing the above-described steps.

### [Other Steps]

The manufacturing method according to the embodiment of the present invention may include a step of curing the light absorption anisotropic film after the above-described alignment step (hereinafter, also referred to as “curing step”).

The curing step is performed by, for example, heating the light absorption anisotropic film and/or irradiating (exposing) the light absorption anisotropic film with light. Among these, it is preferable that the curing step is performed by irradiating the light absorption anisotropic layer with light.

Various light sources such as infrared rays, visible light, and ultraviolet rays can be used as a light source for curing, but ultraviolet rays are preferable. In addition, ultraviolet rays may be applied while the film is heated during curing, or ultraviolet rays may be applied through a filter which transmits only a specific wavelength.

In addition, the exposure may be performed under a nitrogen atmosphere. In a case where the curing of the light absorption anisotropic film proceeds by radical polymerization, since inhibition of polymerization by oxygen is reduced, it is preferable that the exposure is performed in a nitrogen atmosphere.

### [Suitable Aspect 1]

As one suitable aspect of the manufacturing method according to the embodiment of the present invention, an aspect (suitable aspect 1) in which the alignment step includes a step of exposing the coating film formed in the coating film-forming step to light in the atmosphere (under the atmospheric environment) (hereinafter, also referred to as “atmospheric exposure step”) is exemplified.

In a case where the coating film is exposed to light in the atmosphere, the polymerization is difficult to proceed due to deactivation of radicals in the region (region A) on the coating surface side, whereas the polymerization proceeds (half-cured) in the region (region B) on the alignment film side. As a result, it is considered that a light absorption anisotropic film in which the viscosity of the region B is increased, the formation rate of the arrangement structure of the dichroic substance in the region B is decreased, and the size (Llow) of the arrangement structure in the region B is small can be obtained. The value of Llow can be further adjusted depending on irradiation conditions (illuminance, irradiation time, and the like) of the exposure.

From the reason that the effects and the like of the present invention are more excellent, it is preferable that the atmospheric exposure step is performed after the above-described first stage heating treatment is performed and the temperature is cooled to approximately room temperature and before the second stage heating treatment.

In the atmospheric exposure step, from the reason that the effects and the like of the present invention are more excellent, the illuminance is preferably 1 to 300 mW/cm², more preferably 10 to 250 mW/cm², and still more preferably 20 to 200 mW/cm².

In the atmospheric exposure step, from the reason that the effects and the like of the present invention are more excellent, the irradiation time is preferably 0.05 to 10 seconds, more preferably 0.07 to 5 seconds, and still more preferably 0.1 to 2 seconds.

### [Suitable Aspect 2]

In addition, as another suitable aspect of the manufacturing method according to the embodiment of the present invention, an aspect (suitable aspect 2) in which the alignment step includes a step of exposing the coating film formed in the coating film-forming step to ultraviolet rays not including light of 330 nm or more (hereinafter, also referred to as “short-wavelength UV”) (hereinafter, also referred to as “short-wavelength UV exposure step”) is exemplified.

In a case where the coating film is exposed to the short-wavelength UV, the polymerization proceeds in the region (region A) on the coating surface side (half curing), but the polymerization is difficult to proceed in the region (region B) on the alignment film side because the short-wavelength UV is difficult to transmit. As a result, it is considered that a light absorption anisotropic film in which the viscosity of the region A is increased, the formation rate of the arrangement structure of the dichroic substance in the region A is decreased, and the size (Ltop) of the arrangement structure in the region A is small can be obtained. The value of Ltop can be further adjusted depending on irradiation conditions (illuminance, irradiation time, and the like) of the exposure.

Examples of a method of generating the short-wavelength UV include a method of performing UV exposure through a short pass filter.

From the reason that the effects and the like of the present invention are more excellent, it is preferable that the short-wavelength UV exposure step is performed after the above-described first stage heating treatment is performed and the temperature is cooled to approximately room temperature and before the second stage heating treatment.

In the short-wavelength UV exposure step, from the reason that the effects and the like of the present invention are more excellent, the illuminance is preferably 1 to 500 mW/cm², more preferably 10 to 400 mW/cm², and still more preferably 20 to 300 mW/cm².

In the short-wavelength UV exposure step, from the reason that the effects and the like of the present invention are more excellent, the irradiation time is preferably 0.05 to 10 seconds, more preferably 0.07 to 5 seconds, and still more preferably 0.1 to 2 seconds.

### [3] Laminate

The laminate according to the embodiment of the present invention is a laminate including the above-described light absorption anisotropic film according to the embodiment of the present invention.

The laminate according to the embodiment of the present invention may include a film (layer) other than the film according to the embodiment of the present invention. Examples of such a film (layer) include a protective layer, an alignment film, a base material, and an optically anisotropic film.

In a case where the laminate according to the embodiment of the present invention is applied to an image display device, it is preferable that a protective layer side is positioned on a visible side (light incident side). By disposing a surface having a low polarization degree (a surface having a low refractive index) on the protective layer side, a difference in refractive index between the light absorption anisotropic film and the protective layer is reduced, and internal reflection can be further suppressed.

### [Light Absorption Anisotropic Film]

The light absorption anisotropic film according to the embodiment of the present invention, which is included in the laminate according to the embodiment of the present invention, is as described above, and thus the description thereof will not be repeated.

### [Protective Layer]

The protective layer is not particularly limited, and examples thereof include an oxygen-shielding layer and a ultraviolet (UV) absorbing layer; and from the reason that the effects and the like of the present invention are more excellent, an oxygen-shielding layer is preferable.

### [Oxygen-Shielding Layer]

The oxygen-shielding layer is an oxygen-shielding film having an oxygen shielding function. In the present specification, the oxygen shielding function is not limited to a function for making a state in which oxygen is not allowed to pass through the layer, and also includes a function for making a state in which a small amount of oxygen is allowed to pass through the layer depending on the desired performance.

Specific examples of the oxygen-shielding layer include layers containing organic compounds such as polyvinyl alcohol, modified polyvinyl alcohol, polyethylene vinyl alcohol, polyvinyl ether, polyvinylpyrrolidone, polyacrylamide, polyacrylic acid, cellulose ether, polyamide, polyimide, a styrene/maleic acid copolymer, gelatin, vinylidene chloride, and cellulose nanofibers; and from the reason that the effects and the like of the present invention are more excellent, polyacrylic acid, polyvinyl alcohol, or modified polyvinyl alcohol is preferable.

From the viewpoint of further improving light resistance, the oxygen-shielding layer may further contain a light resistance improving agent together with the above-described organic compound. In a case where the oxygen-shielding layer contains the light resistance improving agent, a content of the light resistance improving agent is preferably 0.1% to 5.0% by mass and more preferably 0.3% to 3.0% by mass with respect to the total mass of the oxygen-shielding layer.

From the reason that the effects and the like of the present invention are more excellent, a thickness of the oxygen-shielding layer is preferably 0.1 to 10 μm and more preferably 0.5 to 5.5 μm.

From the reason that the effects and the like of the present invention are more excellent, a refractive index of the protective layer at a wavelength of 550 nm is preferably 1.40 to 1.60 and more preferably 1.45 to 1.55.

Here, the refractive index of the protective layer at a wavelength of 550 nm can be measured by the same method as for the average refractive index of the light absorption anisotropic film described above.

### [Alignment Film]

The alignment film of the laminate according to the embodiment of the present invention is the same as the alignment film used in the above-described manufacturing method of a light absorption anisotropic film, and thus the description thereof will not be repeated.

### [Base Material]

The laminate according to the embodiment of the present invention may include a base material on a surface side of the alignment film opposite to the light absorption anisotropic film. The base material can be selected depending on applications of the light absorption anisotropic film, and examples thereof include glass and a polymer film.

In a case where a polymer film is used as the base material, it is preferable to use an optically isotropic polymer film. As specific examples and preferred aspects of the polymer, the description in paragraph [0013] of JP2002-22942A can be applied. In addition, even in a case of a polymer easily exhibiting birefringence, such as polycarbonate and polysulfone which has been known in the related art, a polymer with the exhibiting property which has been decreased by modifying the molecules, described in WO2000/26705A, can also be used.

A visible light average transmittance of the base material is preferably 80% or more.

### [Optically Anisotropic Film]

It is preferable that the laminate according to the embodiment of the present invention includes an optically anisotropic film (optically anisotropic layer).

Here, the optically anisotropic film refers to all films showing a retardation, and examples thereof include a stretched polymer film and a retardation film provided with an optically anisotropic layer having a liquid crystal compound aligned on a support.

Here, the alignment direction of the liquid crystalline compound contained in the optically anisotropic layer is not particularly limited, and examples thereof include horizontal alignment, vertical alignment, and twisted alignment with respect to the film surface.

In addition, a λ/4 plate, a λ/2 plate, and the like have specific functions of the optically anisotropic film.

In addition, the optically anisotropic layer may be formed of a plurality of layers. Regarding the optically anisotropic layer formed of a plurality of optically anisotropic layers, for example, the description in paragraphs [0008] to [0053] of JP2014-209219A can be referred to.

In addition, such an optically anisotropic film and the above-described light absorption anisotropic film may be provided by coming into contact with each other, or another layer may be provided therebetween. Examples of such a layer include the above-described alignment film, and a pressure-sensitive adhesive layer or an adhesive layer for ensuring the adhesiveness.

It is preferable that the laminate according to the embodiment of the present invention uses a λ/4 plate as the above-described optically anisotropic film and has the λ/4 plate on the surface side of the alignment film opposite to the light absorption anisotropic film described above.

Here, the “λ/4 plate” is a plate having a λ/4 function, specifically, a plate having a function of converting linearly polarized light having a specific wavelength into circularly polarized light (or converting circularly polarized light into linearly polarized light).

Specific examples of an aspect in which the λ/4 plate has a monolayer structure include a stretched polymer film and a retardation film in which an optically anisotropic layer having a λ/4 function is provided on a support. In addition, specific examples of an aspect in which the λ/4 plate has a multilayer structure include a broadband λ/4 plate obtained by laminating a λ/4 plate and a λ/2 plate.

The λ/4 plate may be a λ/4 plate formed of a reverse dispersive liquid crystal compound and having wavelength dispersibility of a retardation Re which is reverse-dispersive wavelength dispersibility. Here, the reverse-dispersive wavelength dispersibility refers to that Re(λ) and Rth(λ) have larger values as the wavelength, increases, and in this case, the phase difference Re(λ) satisfies the following expressions (Re-1) and (Re-2).

$$Re ( 450 ) / Re ( 550 ) < 1. \qquad Expression ( Re - 1 )$$

$$Re ( 650 ) / Re ( 550 ) > 1. \qquad Expression ( Re - 2 )$$

In a case where the wavelength dispersibility of the retardation Re has reverse-dispersive wavelength dispersibility, reflection of external light can be reduced in all wavelength ranges of visible light and the tinting of reflected light can be suppressed, which is preferable.

### [4] Image Display Device

The image display device according to the embodiment of the present invention is an image display device including the above-described light absorption anisotropic film (polarizer) according to the embodiment of the present invention.

A display element used in the image display device according to the embodiment of the present invention is not particularly limited, and examples thereof include a liquid crystal cell, an organic electroluminescence (organic EL) display panel, and a plasma display panel. Among these, a liquid crystal cell or an organic EL display panel is preferable, and an organic EL display panel is more preferable. That is, the display device according to the embodiment of the present invention is preferably a liquid crystal display device using a liquid crystal cell as the display element or an organic EL display device using an organic EL display panel as the display element, and is more preferably an organic EL display device.

### [Liquid Crystal Display Device]

A liquid crystal display device which is an example of the display device according to the embodiment of the present invention is a liquid crystal display device which includes the above-described laminate according to the embodiment of the present invention (however, not including the a/4 plate) and a liquid crystal cell.

In the present invention, between the laminates provided on both sides of the liquid crystal cell, it is preferable that the laminate according to the embodiment of the present invention is used as a front-side (viewing side) polarizer and more preferable that the laminate according to the embodiment of the present invention is used as a front-side polarizer and a rear-side polarizer.

Hereinafter, the liquid crystal cell constituting the liquid crystal display device will be described in detail.

### [Liquid Crystal Cell]

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in the TN mode, during non-voltage application, rod-like liquid crystal molecules (rod-like liquid crystal compound) are substantially horizontally aligned and further twisted and aligned at 600 to 120°. The liquid crystal cell in a TN mode is most frequently used as a color TFT liquid crystal display device and is described in a plurality of documents.

In the liquid crystal cell in a VA mode, rod-like liquid crystalline molecules are substantially vertically aligned at the time of no voltage application. Examples of the liquid crystal cell in the VA mode includes (1) a liquid crystal cell in the VA mode in a narrow sense where rod-like liquid crystal molecules are substantially vertically aligned during non-voltage application and are substantially horizontally aligned during voltage application (described in JP1990-176625A (JP-H2-176625A)), (2) a liquid crystal cell (in a multi-domain vertical alignment (MVA) mode) where multiple domains are provided in the VA mode (described in SID97, Digest of tech. Papers (proceedings), 28 (1997) 845) to expand the viewing angle, (3) a liquid crystal cell in an axially symmetric aligned microcell (n-ASM) mode in which rod-like liquid crystal molecules are substantially vertically aligned during non-voltage application and are twisted and aligned in multi-domains during voltage application (described in proceedings of Japanese Liquid Crystal Conference, pp. 58 to 59 (1998)), and (4) a liquid crystal cell in a SURVIVAL mode (presented at liquid crystal cell (LCD) International 98). The liquid crystal cell may be any one of a patterned vertical alignment (PVA) type, an optical alignment type, and a polymer-sustained alignment (PSA) type. These modes are described in detail in JP2006-215326A and JP2008-538819A.

In the liquid crystal cell in an IPS mode, rod-like liquid crystalline molecules are aligned substantially parallel to the substrate, and the liquid crystalline molecules respond planarly through application of an electric field parallel to the substrate surface. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

As an organic EL display device which is an example of the display device according to the embodiment of the present invention, an embodiment of a display device including the above-described laminate (preferably including the λ/4 plate) according to the embodiment of the present invention and an organic EL display panel in this order from the viewing side is suitably exemplified. In this case, it is preferable that the laminate is formed such that the protective layer, the light absorption anisotropic film, the alignment film, and the λ/4 plate are disposed in this order from the viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to Examples. Materials, used amounts, ratios, treatment contents, treatment procedures, and the like described in Examples can be appropriately changed without departing from the spirit of the present invention. Therefore, the scope of the present invention should not be construed as being limited to Examples.

### Example 1

### (Production of Transparent Support)

The following composition was put into a mixing tank and stirred, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88 | |
| Polyester compound B described in Examples | 12 parts by mass |
| of JP2015-227955A | |
| Compound F shown below | 2 parts by mass |
| Methylene chloride (first solvent) | 430 parts by mass |
| Methanol (second solvent) | 64 parts by mass |

Compound F

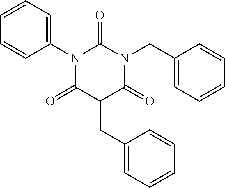 [SMILES: O=C1C(Cc2ccccc2)C(=O)N(c2ccccc2)C(=O)N1Cc1ccccc1]

10 parts by mass of the following matte agent solution was added to 90 parts by mass of the core layer cellulose acylate dope to prepare a cellulose acetate solution to be used as an outer layer cellulose acylate dope.

Matting agent solution

| | |
|---|---|
| Silica particles having an average particle | 2 parts by mass |
| diameter of 20 nm (AEROSIL R972, | |
| manufactured by Nippon Aerosil Co., Ltd.) | |
| Methylene chloride (first solvent) | 76 parts by mass |
| Methanol (second solvent) | 11 parts by mass |
| Core layer cellulose acylate dope described above | 1 part by mass |

The core layer cellulose acylate dope and the outer layer cellulose acylate dope were filtered through filter paper having an average hole diameter of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film on the drum was peeled off in a state in which the solvent content in the film was approximately 20% by mass, both ends of the film in the width direction were fixed by tenter clips, and the film was dried while being stretched at a stretching ratio of 1.1 times in the lateral direction.

Thereafter, the obtained film was further dried by being transported between the rolls of the heat treatment device to produce a transparent support having a thickness of 40 μm, and the transparent support was used as a cellulose acylate film A1.

### [Formation of Photo-Alignment Film B1]

The above-described cellulose acylate film A1 was continuously coated with a composition for forming a photo-alignment film described below with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film B1, thereby obtaining a triacetyl cellulose (TAC) film with the photo-alignment film. A film thickness of the photo-alignment film B1 was 0.25 μm.

Composition for forming alignment film

| | |
|---|---|
| Polymer PA-1 shown below | 100.00 parts by mass |
| Acid generator PAG-1 shown below | 8.25 parts by mass |
| Stabilizer DIPEA shown below | 0.6 parts by mass |
| Xylene | 1126.60 parts by mass |
| Methyl isobutyl ketone | 125.18 parts by mass |

Polymer PA-1 (in the formulae, the numerical value described in each repeating unit denotes the content (% by mass) of each repetition unit with respect to all repeating units) 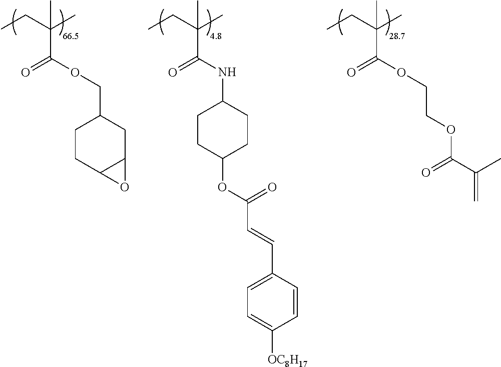
Acid generator PAG-1 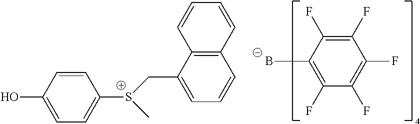
Stabilizer DIPEA

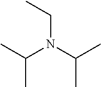

### [Production of Light Absorption Anisotropic Film C1]

### <Coating Film-Forming Step>

A composition for forming a light absorption anisotropic film, having the following formulation, was continuously applied onto the obtained photo-alignment film B1 using a wire bar to form a coating film.

### <Alignment Step>

Next, the coating film was heated at 140° C. for 15 seconds, and then cooled to room temperature (23° C.).

Next, the coating film was heated at 75° C. for 60 seconds, and cooled to room temperature again.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 m) on the photo-alignment film B1.

In a case where a transmittance of the light absorption anisotropic film C1 in a wavelength range of 280 to 780 nm was measured with a spectrophotometer, the average transmittance of visible light was 42%. The absorption axis of the light absorption anisotropic film C1 was orthogonal to a width direction of the cellulose acylate film A1.

In the light absorption anisotropic film C1, the surfactant was unevenly distributed near the surface of the coating surface side, and accordingly, the polyethylene oxide (PEO) having high affinity with the surfactant (having a low Log P value (octanol/water partition coefficient)) was also unevenly distributed in the region A on the coating surface side.

Formulation of composition for forming light absorption anisotropic film (Example 1)

| | |
|---|---|
| First dichroic substance Dye-C1 shown below | 0.69 parts by mass |
| Second dichroic substance Dye-M1 shown below | 0.14 parts by mass |
| Third dichroic substance Dye-Y1 shown below | 0.25 parts by mass |
| Liquid crystal compound (L-1) shown below | 3.16 parts by mass |
| Rod-like liquid crystal compound (L-2) shown below | 1.40 parts by mass |
| Polymerization initiator IRGACURE OXE-02 (manufactured by BASF) | 0.18 parts by mass |
| Polyethylene oxide (Mw = 100,000) | 0.12 parts by mass |
| Surfactant (F-1) shown below | 0.01 parts by mass |
| Cyclopentanone | 91.86 parts by mass |
| Benzyl alcohol | 2.36 parts by mass |

Dichroic substance Dye-C1 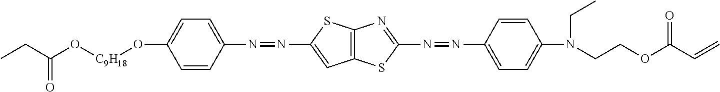
Dichroic substance Dye-M1 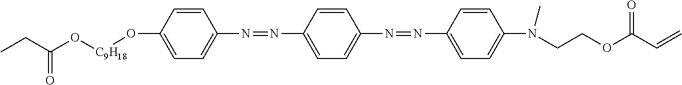
Dichroic substance Dye-Y1 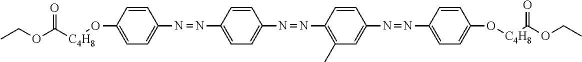
Liquid crystal compound (L-1) (in the formulae, the numerical value (“59”, “15”, or “26”) described in each repeating unit denotes the content (% by mass) of each repetition with respect to all repeating units) 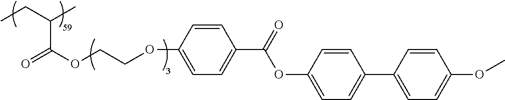 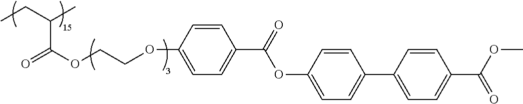 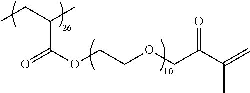
Rod-like liquid crystal compound (L-2) (in the formulae, the numerical value described in each compound represents the content (% by mass) of each compound with respect to all compounds) 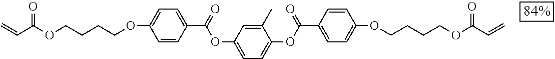 [SMILES: C=CC(=O)OCCCCOc1ccc(C(=O)Oc2ccc(OC(=O)c3ccc(OCCCCOC(=O)C=C)cc3)c(C)c2)cc1] 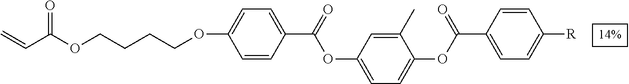 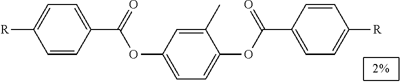 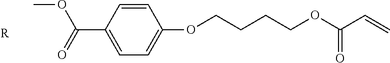
Surfactant (F-1) (in the formulae, the numerical value described in each repeating unit denotes the content (% by mass) of each repetition with respect to all repeating units)

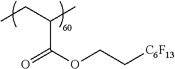

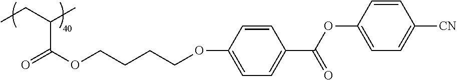

### [Formation of Oxygen-Shielding Layer D1]

The light absorption anisotropic film C1 was continuously coated with a coating liquid D1 having the following formulation with a wire bar. Thereafter, the film was dried with hot air at 80° C. for 5 minutes, thereby obtaining a laminate on which an oxygen-shielding layer D1 consisting of polyvinyl alcohol (PVA) and having a thickness of 1.0 μm was formed, that is, obtaining a laminate CP1 in which the cellulose acylate film A1 (transparent support), the photo-alignment film B1, the light absorption anisotropic film C1, and the oxygen-shielding layer D1 were provided adjacent to each other in this order.

Formulation of coating liquid D1 for forming oxygen-shielding layer

| | |
|---|---|
| Modified polyvinyl alcohol shown below | 3.80 parts by mass |
| Initiator IRGACURE 2959 | 0.20 parts by mass |
| Water | 70 parts by mass |
| Methanol | 30 parts by mass |

Modified polyvinyl alcohol (in the formulae, the numerical value described in each repeating unit represents a content (% by mass) of each repeating unit with respect to all repeating units)

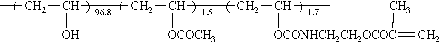

### [Production of TAC Film Including Positive a Plate]

The above-described cellulose acylate film A1 was continuously coated with a coating liquid E1 for forming a photo-alignment film, having the following formulation, with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film E1 having a thickness of 0.2 μm, thereby obtaining a TAC film with the photo-alignment film.

Coating liquid E1 for forming photo-alignment film

| | |
|---|---|
| Polymer PA-2 shown below | 100.00 parts by mass |
| Acid generator PAG-1 described above | 5.00 parts by mass |
| Acid generator CPI-110TF shown below | 0.005 parts by mass |
| Isopropyl alcohol | 16.50 parts by mass |
| Butyl acetate | 1072.00 parts by mass |
| Methyl ethyl ketone | 268.00 parts by mass |

Acid generator CPI-110TF 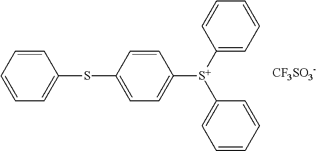
Polymer PA-2 (in the formulae, the numerical value described in each repeating unit denotes the content (% by mass) of each repetition with respect to all repeating units)

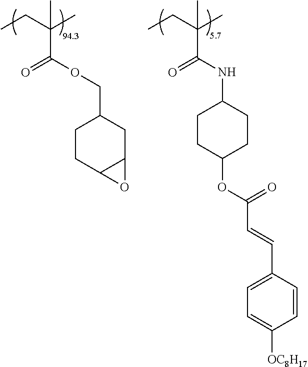

The above-described photo-alignment film E1 was coated with a composition F1 having the following formulation using a bar coater. The coating film formed on the photo-alignment film E1 was heated to 120° C. with hot air, cooled to 60° C., irradiated with ultraviolet rays having a wavelength of 365 nm with an illuminance of 100 mJ/cm² using a high-pressure mercury lamp in a nitrogen atmosphere, and continuously irradiated with ultraviolet rays with an illuminance of 500 mJ/cm² while being heated at 120° C., so that the alignment of the liquid crystal compound was immobilized, thereby producing a TAC film having a positive A plate F1.

A thickness of the positive A plate F1 was 2.5 μm, and an Re(550) was 144 nm. In addition, the positive A plate satisfied a relationship of “Re(450)≤Re(550)≤Re(650)”. Re(450)/Re(550) was 0.82.

Composition F1

| | |
|---|---|
| Polymerizable liquid crystal compound LA-1 shown below | 43.50 parts by mass |
| Polymerizable liquid crystal compound LA-2 shown below | 43.50 parts by mass |
| Polymerizable liquid crystal compound LA-3 shown below | 8.00 parts by mass |
| Polymerizable liquid crystal compound LA-4 shown below | 5.00 parts by mass |
| Polymerization initiator PI-1 shown below | 0.55 parts by mass |
| Leveling agent T-1 shown below | 0.20 parts by mass |
| Cyclopentanone | 235.00 parts by mass |

Polymerizable liquid crystal compound LA-1 (tBu represents a tertiary butyl group) 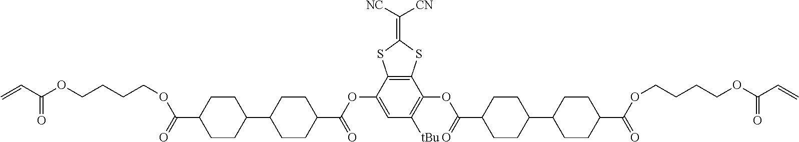 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-2 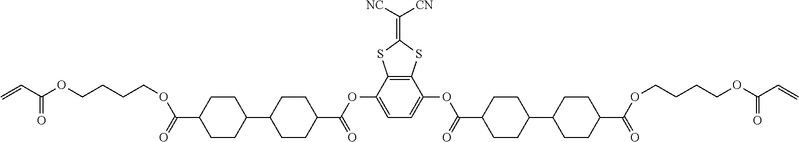 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-3 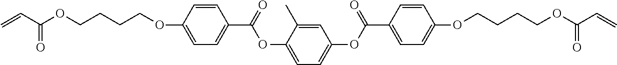 [SMILES: C=CC(=O)OCCCCOc1ccc(C(=O)Oc2ccc(OC(=O)c3ccc(OCCCCOC(=O)C=C)cc3)c(C)c2)cc1]
Polymerizable liquid crystal compound LA-4 (Me represents a methyl group) 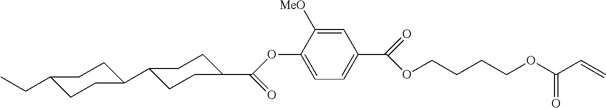 [SMILES: C=CC(=O)OCCCCOC(=O)c1ccc(OC(=O)C2CCC(C3CCC(CC)CC3)CC2)c(OC)c1]
Polymerization initiator PI-1 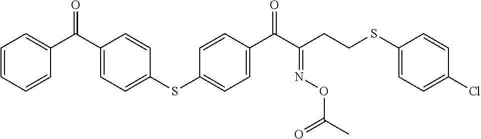 [SMILES: CC(=O)O/N=C(\CCSc1ccc(Cl)cc1)C(=O)c1ccc(Sc2ccc(C(=O)c3ccccc3)cc2)cc1]
Leveling agent T-1 (in the formulae, the numerical value described in each repeating unit denotes the content (% by mass) of each repetition with respect to all repeating units)

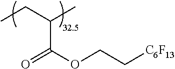

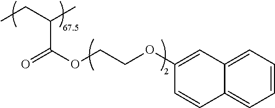

### [Production of TAC Film Including Positive C Plate H1]

The above-described cellulose acylate film A1 was used as a temporary support. After passing the cellulose acylate film A1 through a dielectric heating roll at a temperature of 60° C. to raise the film surface temperature to 40° C., an alkaline solution having the formulation shown below was applied onto one surface of the film using a bar coater at a coating amount of 14 ml/m², followed by heating to 110° C., and transportation of the film under a steam type far-infrared heater manufactured by Noritake Company Limited for 10 seconds.

Next, the film was coated with pure water such that the coating amount reached 3 ml/m² using the same bar coater. Next, the film was washed with water by a fountain coater and drained by an air knife three times, and then transported to a drying zone at 70° C. for 10 seconds and dried to produce a cellulose acylate film A1 subjected to an alkali saponification treatment.

(Alkaline solution)

| | |
|---|---|
| Potassium hydroxide | 4.7 parts by mass |
| Water | 15.8 parts by mass |
| Isopropanol | 63.7 parts by mass |
| Fluorine-containing surfactant SF-1 | 1.0 part by mass |
| (C₁₄H₂₉O(CH₂CH₂O)₂₀H) | |
| Propylene glycol | 14.8 parts by mass |

The cellulose acylate film A1 which had been subjected to the alkali saponification treatment was continuously coated with a coating liquid G1 for forming a photo-alignment film, having the following formulation, using a #8 wire bar. The obtained film was dried with hot air at 60° C. for 60 seconds, and further dried with hot air at 100° C. for 120 seconds to form a photo-alignment film G1.

Coating liquid G1 for forming photo-alignment film

| | |
|---|---|
| Polyvinyl alcohol (PVA103 manufactured | 2.4 parts by mass |
| by Kuraray Co., Ltd.) | |
| Isopropyl alcohol | 1.6 parts by mass |
| Methanol | 36 parts by mass |
| Water | 60 parts by mass |

The photo-alignment film G1 was coated with a coating liquid H1 for forming a positive C plate, having the following formulation, the obtained coating film was aged at 60° C. for 60 seconds and irradiated with ultraviolet rays at an illuminance of 1000 mJ/cm² in the air using an air-cooled metal halide lamp at an illuminance of 70 mW/cm² (manufactured by Eye Graphics Co., Ltd.), and the alignment state thereof was fixed to vertically align the liquid crystal compound, thereby producing a TAC film having a positive C plate H1 with a thickness of 0.5 μm.

Rth(550) of the obtained positive C plate was −60 nm.

Coating liquid H1 for forming positive C plate

| | |
|---|---|
| Liquid crystal compound LC-1 shown below | 80 parts by mass |
| Liquid crystal compound LC-2 shown below | 20 parts by mass |
| Vertically aligned liquid crystal compound S01 shown below | 1 part by mass |
| Ethylene oxide-modified trimethylolpropane triacrylate (V # 360, manufactured by Osaka | 8 parts by mass |
| Organic Chemical Industry Ltd.) | |
| IRGACURE 907 (manufactured by BASF SE) | 3 parts by mass |
| KAYACURE DETX (manufactured by Nippon Kayaku Co., Ltd.) | 1 part by mass |
| Compound B03 shown below | 0.4 parts by mass |
| Methyl ethyl ketone | 170 parts by mass |
| Cyclohexanone | 30 parts by mass |

Liquid crystal compound LC-1 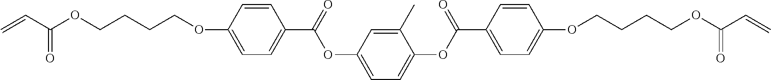 [SMILES: C=CC(=O)OCCCCOc1ccc(C(=O)Oc2ccc(OC(=O)c3ccc(OCCCCOC(=O)C=C)cc3)c(C)c2)cc1]
Liquid crystal compound LC-2 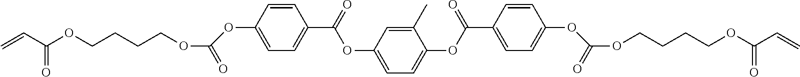 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]
Vertically aligned liquid crystal compound S01 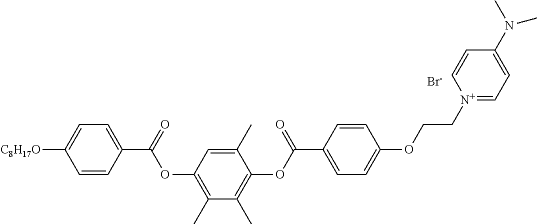
Compound B03 (in the formulae, the numerical value described in each repeating unit denotes the content (% by mass) of each repetition with respect to all repeating units)

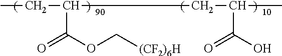

### [Production of Pressure Sensitive Adhesives N1 and N2]

An acrylate-based polymer was prepared according to the following procedure. 95 parts by mass of butyl acrylate and 5 parts by mass of acrylic acid were polymerized by a solution polymerization method in a reaction container equipped with a cooling pipe, a nitrogen introduction pipe, a thermometer, and a stirrer, thereby obtaining an acrylate-based polymer (NA1) with an average molecular weight of 2,000,000 and a molecular weight distribution (Mw/Mn) of 3.0.

Next, an acrylate-based pressure sensitive adhesive was produced with the following formulation using the obtained acrylate-based polymer (NA1). Each separate film which had been subjected to a surface treatment with a silicone-based release agent was coated with the composition using a die coater, dried in an environment of 90° C. for 1 minute, and irradiated with ultraviolet rays (UV) under the following conditions, thereby obtaining the following acrylate-based pressure sensitive adhesives N1 and N2 (pressure-sensitive adhesive layers). The formulation and the film thickness of the acrylate-based pressure sensitive adhesive are shown below.

### <UV Irradiation Conditions>

Electrodeless lamp H bulb (Fusion Co., Ltd.)
Illuminance: 600 mW/cm², light intensity: 150 mJ/cm²
The UV illuminance and the light intensity were measured using “UVPF-36” (manufactured by Eye Graphics Co., Ltd.).

Acrylate-based pressure sensitive adhesive N1 (film thickness: 15 μm)

| | |
|---|---|
| Acrylate-based polymer (NA1) | 100 parts by mass |
| (A) Polyfunctional acrylate-based monomer | 11.1 parts by mass |
| shown below | |
| (B) Photopolymerization initiator shown below | 1.1 parts by mass |
| (C) Isocyanate-based crosslinking agent | 1.0 part by mass |
| shown below | |
| (D) Silane coupling agent shown below | 0.2 parts by mass |

Acrylate-based pressure sensitive adhesive N2 (film thickness: 25 μm)

| | |
|---|---|
| Acrylate-based polymer (NA1) | 100 parts by mass |
| (C) Isocyanate-based crosslinking agent | 1.0 part by mass |
| shown below | |
| (D) Silane coupling agent shown below | 0.2 parts by mass |

(A) Polyfunctional acrylate-based monomer: tris(acryloyloxyethyl) isocyanurate, molecular weight=423, trifunctional type (manufactured by Toagosei Co., Ltd., trade name “ARONIX M-315”)
(B) Photopolymerization initiator: mixture of benzophenone and 1-hydroxycyclohexyl phenyl ketone at mass ratio of 1:1, “IRGACURE 500” manufactured by Ciba Specialty Chemicals Corp.
(C) Isocyanate-based crosslinking agent: trimethylolpropane-modified tolylene diisocyanate (“CORONATE L” manufactured by Nippon Polyurethane Industry Co., Ltd.)
(D) Silane coupling agent: 3-glycidoxypropyltrimethoxysilane (“KBM-403” manufactured by Shin-Etsu Chemical Co., Ltd.)

### [Production of UV Adhesive]

An UV adhesive composition having the following composition was prepared.

UV adhesive composition

| | |
|---|---|
| CEL2021P (manufactured by Daicel Corporation) | 70 parts by mass |
| 1,4-Butanediol diglycidyl ether | 20 parts by mass |
| 2-Ethylhexyl glycidyl ether | 10 parts by mass |
| CPI-100P | 2.25 parts by mass |

CPI-100P

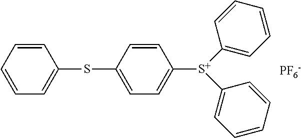

### [Production of Laminate CPAC1]

The above-described TAC film having the positive A plate F1 on the phase difference side and the above-described TAC film having the positive C plate H1 on the phase difference side were bonded to each other by irradiation with UV rays of 600 mJ/cm² using the above-described UV adhesive composition. A thickness of the UV adhesive layer was 3 μm. The surfaces bonded to each other with the UV adhesive were respectively subjected to a corona treatment. Next, the photo-alignment film E1 on the positive A plate F1 side and the cellulose acylate film A1 were removed to obtain a retardation plate AC1. The retardation plate AC1 had a layer configuration of the positive A plate F1, the UV adhesive layer, the positive C plate H1, the photo-alignment film G1, and the cellulose acylate film A1.

The above-described laminate CP1 on the oxygen-shielding layer D1 side was bonded to a low-reflection surface film CV-LC5 (manufactured by FUJIFILM Corporation) on a support side using the above-described pressure sensitive adhesive N1. Next, only the cellulose acylate film A1 of the above-described laminate CP1 was removed, and the surface from which the film had been removed and the retardation plate AC1 on the positive A plate F1 side were bonded to each other using the above-described pressure sensitive adhesive N1. Next, the photo-alignment film G1 on the positive C plate H1 side and the cellulose acylate film A1 included in the above-described retardation plate AC1 were removed, thereby producing a laminate CPAC1. At this time, the films were bonded to each other such that an angle between an absorption axis of the light absorption anisotropic film C1 included in the above-described laminate CPAC1 and a slow axis of the positive A plate F1 was set to 45°. The laminate CPAC1 had a layer configuration of the low-reflection surface film CV-LC5, the pressure sensitive adhesive layer N1, the oxygen-shielding layer D1, the light absorption anisotropic film C1, the photo-alignment film B1, the pressure sensitive adhesive N1, the positive A plate F1, the UV adhesive layer, and the positive C plate H1.

[Production of organic EL display device (display device 1)] GALAXY S5 (manufactured by Samsung Electronics Co., Ltd.) equipped with an organic EL panel (organic EL display element) was disassembled, a touch panel provided with a circularly polarizing plate was peeled off from the organic EL display device, and a circularly polarizing plate was further peeled off from the touch panel, so that the organic EL display element, the touch panel, and the circularly polarizing plate were isolated from each other. Subsequently, the isolated touch panel was bonded to the organic EL display element again, and the laminate CPAC1 on the positive C plate H1 side, which had been produced above, was bonded onto the touch panel such that air did not enter, thereby producing an organic EL display device (display device 1).

### [Production of Organic EL Display Device (Display Device 2)]

A laminate CP2 in which the cellulose acylate film A1 (transparent support), the light absorption anisotropic film C1, the photo-alignment film B1, and the oxygen-shielding layer D1 were provided adjacent to each other in this order was obtained according to the same procedure as that for the above-described laminate CP1, except that, after the production of the light absorption anisotropic film C1, the cellulose acylate film A was bonded to the surface of the light absorption anisotropic film C1 opposite to the photo-alignment film B1, and then the cellulose acylate film A on the photo-alignment film B1 side was removed to form the oxygen-shielding layer D1 on the photo-alignment film B1. An organic EL display device (display device 2) was produced according to the same procedure as that for the display device 1, except that the laminate CP2 was used instead of the laminate CP1.

### Example 2

An organic EL display device (display device 1 and display device 2) was produced according to the same procedure as in Example 1, except that a composition for forming a light absorption anisotropic film, having the following formulation, was used as the composition for forming a light absorption anisotropic film.

In the light absorption anisotropic film C1, since EPICLON N-695 had a small ASP value (difference in solubility parameter) with respect to the photo-alignment film B1, EPICLON N-695 was unevenly distributed in the region B on the photo-alignment film B1 side.

Formulation of composition for forming light
absorption anisotropic film (Example 2)

| | |
|---|---|
| First dichroic substance Dye-C1 shown above | 0.69 parts by mass |
| Second dichroic substance Dye-M1 shown above | 0.14 parts by mass |
| Third dichroic substance Dey-Y1 shown above | 0.25 parts by mass |
| Liquid crystal compound (L-1) shown above | 3.16 parts by mass |
| Rod-like liquid crystal compound (L-2) | 1.40 parts by mass |
| shown above | |
| Polymerization initiator IRGACURE | 0.18 parts by mass |
| OXE-02 (manufactured by BASF) | |
| EPICLON N-695 manufactured by DIC | 0.12 parts by mass |
| Corporation | |
| Surfactant (F-1) shown above | 0.01 parts by mass |
| Cyclopentanone | 91.86 parts by mass |
| Benzyl alcohol | 2.36 parts by mass |

EPICLON N-695 (cresol novolac-type epoxy resin) manufactured by DIC Corporation (Mw = 2,100)

### Example 3

An organic EL display device (display device 1 and display device 2) was produced according to the same procedure as in Example 1, except that a composition for forming a light absorption anisotropic film, having the following formulation, was used as the composition for forming a light absorption anisotropic film.

In the light absorption anisotropic film C1, the polyethylene oxide (PEO) was unevenly distributed in the region A on the coating surface side as in Example 1, and the EPICLON N-695 was unevenly distributed in the region B on the photo-alignment film B1 side as in Example 2.

Formulation of composition for forming light
absorption anisotropic film (Example 3)

| | |
|---|---|
| First dichroic substance Dye-C1 shown above | 0.69 parts by mass |
| Second dichroic substance Dye-M1 shown above | 0.14 parts by mass |
| Third dichroic substance Dey-Y1 shown above | 0.25 parts by mass |
| Liquid crystal compound (L-1) shown above | 3.16 parts by mass |
| Rod-like liquid crystal compound (L-2) shown above | 1.40 parts by mass |
| Polymerization initiator | 0.18 parts by mass |
| IRGACURE OXE-02 (manufactured by BASF) | |
| Polyethylene oxide (Mw = 100,000) | 0.12 parts by mass |
| EPICLON N-695 manufactured by DIC Corporation | 0.12 parts by mass |
| Surfactant (F-1) shown above | 0.01 parts by mass |
| Cyclopentanone | 91.86 parts by mass |
| Benzyl alcohol | 2.36 parts by mass |

### Example 4

An organic EL display device (display device 1 and display device 2) was produced according to the same procedure as in Example 1, except that the light absorption anisotropic film C1 was produced as follows.

### [Production of Light Absorption Anisotropic Film C1]

### <Coating Film-Forming Step>

A composition for forming a light absorption anisotropic film, having the following formulation, was continuously applied onto the photo-alignment film B1 using a wire bar to form a coating film.

### <Alignment Step>

Next, the coating film was heated at 140° C. for 15 seconds, and then cooled to room temperature (23° C.).

Next, the coating film was irradiated with a light emitting diode (LED) lamp (central wavelength: 365 nm) for 0.5 seconds in an atmosphere under an irradiation condition of an illuminance of 10 mW/cm².

Next, the coating film was heated at 75° C. for 60 seconds, and cooled to room temperature again.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 m) on the photo-alignment film B1.

In a case where a transmittance of the light absorption anisotropic film C1 in a wavelength range of 280 to 780 nm was measured with a spectrophotometer, the average transmittance of visible light was 42%.

The absorption axis of the light absorption anisotropic film C1 was orthogonal to a width direction of the cellulose acylate film A1.

Formulation of composition for forming light
absorption anisotropic film (Examples 4 to 7)

| | |
|---|---|
| First dichroic substance Dye-C1 shown above | 0.69 parts by mass |
| Second dichroic substance Dye-M1 shown above | 0.14 parts by mass |
| Third dichroic substance Dey-Y1 shown above | 0.25 parts by mass |
| Liquid crystal compound (L-1) shown above | 3.16 parts by mass |
| Rod-like liquid crystal compound (L-2) shown above | 1.40 parts by mass |
| Polymerization initiator IRGACURE OXE-02 | 0.18 parts by mass |
| (manufactured by BASF) | |
| Surfactant (F-1) shown above | 0.01 parts by mass |
| Cyclopentanone | 91.86 parts by mass |
| Benzyl alcohol | 2.36 parts by mass |

### Example 5

An organic EL display device (display device 1 and display device 2) was produced according to the same procedure as in Example 1, except that the light absorption anisotropic film C1 was produced as follows.

### [Production of Light Absorption Anisotropic Film C1]

### <Coating Film-Forming Step>

A composition for forming a photoanisotropic film, having the same composition as that of Example 4, was continuously applied onto the photo-alignment film B1 using a wire bar to form a coating film.

### <Alignment Step>

Next, the coating film was heated at 140° C. for 15 seconds, and then cooled to room temperature (23° C.).

Next, the coating film was irradiated with a light emitting diode (LED) lamp (central wavelength: 365 nm) for 1 second in an atmosphere under an irradiation condition of an illuminance of 20 mW/cm².

Next, the coating film was heated at 75° C. for 60 seconds, and cooled to room temperature again.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 m) on the photo-alignment film B1.

In a case where a transmittance of the light absorption anisotropic film C1 in a wavelength range of 280 to 780 nm was measured with a spectrophotometer, the average transmittance of visible light was 42%.

The absorption axis of the light absorption anisotropic film C1 was orthogonal to a width direction of the cellulose acylate film A1.

### Example 6

An organic EL display device (display device 1 and display device 2) was produced according to the same procedure as in Example 1, except that the light absorption anisotropic film C1 was produced as follows.

### [Production of Light Absorption Anisotropic Film C1]

### <Coating Film-Forming Step>

A composition for forming a photoanisotropic film, having the same composition as that of Example 4, was continuously applied onto the photo-alignment film B1 using a wire bar to form a coating film.

### <Alignment Step>

Next, the coating film was heated at 140° C. for 15 seconds, and then cooled to room temperature (23° C.).

Next, the coating film was irradiated with light for 2 seconds under an irradiation condition of an illuminance of 50 mW/cm² using a high-pressure mercury lamp equipped with a short pass filter of 310 nm.

Next, the coating film was heated at 75° C. for 60 seconds, and cooled to room temperature again.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 m) on the photo-alignment film B1.

In a case where a transmittance of the light absorption anisotropic film C1 in a wavelength range of 280 to 780 nm was measured with a spectrophotometer, the average transmittance of visible light was 42%.

The absorption axis of the light absorption anisotropic film C1 was orthogonal to a width direction of the cellulose acylate film A1.

### Example 7

An organic EL display device (display device 1 and display device 2) was produced according to the same procedure as in Example 1, except that the light absorption anisotropic film C1 was produced as follows.

### [Production of Light Absorption Anisotropic Film C1]

### <Coating Film-Forming Step>

A composition for forming a photoanisotropic film, having the same composition as that of Example 4, was continuously applied onto the photo-alignment film B1 using a wire bar to form a coating film.

### <Alignment Step>

Next, the coating film was heated at 140° C. for 15 seconds, and then cooled to room temperature (23° C.).

Next, the coating film was irradiated with light for 2 seconds under an irradiation condition of an illuminance of 10 mW/cm² using a high-pressure mercury lamp equipped with a short-pass filter of 310 nm.

Next, the coating film was heated at 75° C. for 60 seconds, and cooled to room temperature again.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 m) on the photo-alignment film B1.

In a case where a transmittance of the light absorption anisotropic film C1 in a wavelength range of 280 to 780 nm was measured with a spectrophotometer, the average transmittance of visible light was 42%.

The absorption axis of the light absorption anisotropic film C1 was orthogonal to a width direction of the cellulose acylate film A1.

### Example 8

An organic EL display device (display device 1 and display device 2) was produced according to the same procedure as in Example 4, except that, in the production of the light absorption anisotropic film C1, a composition for forming a light absorption anisotropic film, having the following formulation, was used as the composition for forming a light absorption anisotropic film.

Formulation of composition for forming light absorption anisotropic film (Examples 8 and 9)

| | |
|---|---|
| First dichroic substance Dye-C1 shown above | 0.15 parts by mass |
| First dichroic substance Dye-C2 shown below | 0.44 parts by mass |
| Second dichroic substance Dye-M1 shown above | 0.14 parts by mass |
| Third dichroic substance Dey-Y1 shown above | 0.25 parts by mass |
| Liquid crystal compound (L-1) shown above | 3.16 parts by mass |
| Rod-like liquid crystal compound (L-2) shown above | 1.40 parts by mass |
| Polymerization initiator IRGACURE OXE-02 (manufactured by BASF) | 0.18 parts by mass |
| Surfactant (F-1) shown above | 0.01 parts by mass |
| Cyclopentanone | 91.86 parts by mass |
| Benzyl alcohol | 2.36 parts by mass |

Dichroic substance Dye-C2

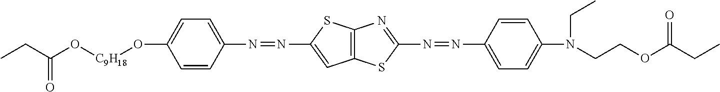

### Example 9

An organic EL display device (display device 1 and display device 2) was produced according to the same procedure as in Example 6, except that, in the production of the light absorption anisotropic film C1, a composition for forming a light absorption anisotropic film, having the same formulation as that of Example 8, was used as the composition for forming a light absorption anisotropic film.

### Example 10

An organic EL display device (display device 1 and display device 2) was produced according to the same procedure as in Example 4, except that, in the production of the light absorption anisotropic film C1, a composition for forming a light absorption anisotropic film, having the following formulation, was used as the composition for forming a light absorption anisotropic film.

Formulation of composition for forming light absorption anisotropic film (Examples 10 and 11)

| | |
|---|---|
| First dichroic substance Dye-C1 shown above | 0.26 parts by mass |
| First dichroic substance Dye-C2 shown above | 0.77 parts by mass |
| Second dichroic substance Dye-M1 shown above | 0.25 parts by mass |
| Third dichroic substance Dey-Y2 shown below | 0.04 parts by mass |
| Liquid crystal compound (L-1) shown above | 3.16 parts by mass |
| Rod-like liquid crystal compound (L-2) shown above | 1.40 parts by mass |
| Polymerization initiator IRGACURE OXE-02 (manufactured by BASF) | 0.18 parts by mass |
| Surfactant (F-1) shown above | 0.01 parts by mass |
| Cyclopentanone | 91.86 parts by mass |
| Benzyl alcohol | 2.36 parts by mass |

Dichroic substance Dey-Y2

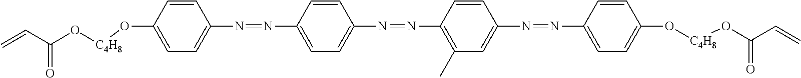

### Example 11

An organic EL display device (display device 1 and display device 2) was produced according to the same procedure as in Example 6, except that, in the production of the light absorption anisotropic film C1, a composition for forming a light absorption anisotropic film, having the same formulation as that of Example 10, was used as the composition for forming a light absorption anisotropic film.

### Example 12

An organic EL display device (display device 1 and display device 2) was produced according to the same procedure as in Example 6, except that, in the production of the light absorption anisotropic film C1, a composition for forming a light absorption anisotropic film, having the following formulation, was used as the composition for forming a light absorption anisotropic film.

Formulation of composition for forming light absorption anisotropic film (Example 12)

| | |
|---|---|
| First dichroic substance Dye-C1 shown above | 0.26 parts by mass |
| First dichroic substance Dye-C2 shown above | 0.77 parts by mass |
| Second dichroic substance Dye-M1 shown above | 0.25 parts by mass |
| Third dichroic substance Dey-Y2 shown above | 0.04 parts by mass |
| Liquid crystal compound (L-3) shown below | 3.42 parts by mass |
| Liquid crystal compound (L-4) shown below | 1.14 parts by mass |
| Polymerization initiator IRGACURE OXE-02 (manufactured by BASF) | 0.18 parts by mass |
| Surfactant (F-1) shown above | 0.01 parts by mass |
| Cyclopentanone | 91.86 parts by mass |
| Benzyl alcohol | 2.36 parts by mass |

Liquid crystal compound (L-3) 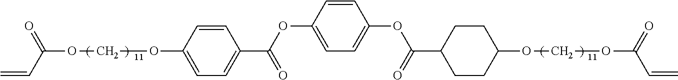
Liquid crystal compound (L-4)

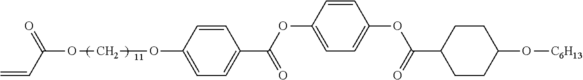

### Comparative Example 1

An organic EL display device (display device 1 and display device 2) was produced according to the same procedure as in Example 1, except that the composition for forming a light absorption anisotropic film of Example 4 was used as the composition for forming a light absorption anisotropic film.

### [Observation of Arrangement Structure]

For the light absorption anisotropic film C1 of each of Examples, Ltop, Llow, and Lmid were measured by the above-described methods. As described above, the region B (Llow) was on the photo-alignment film B1 side, and the region A (Ltop) was on a side opposite to the photo-alignment film B1. The results are shown in Table 1.

### [Evaluation]

The produced organic EL display device was evaluated as follows.

### [Black Density]

A display screen of the produced organic EL display device (display device 1 and display device 2) was set to black display, and reflected light in a case where a fluorescent lamp was projected from the front was observed. Black density was evaluated based on the following standard. The results are shown in Table 1. Practically, it is preferable that at least one of the display device 1 or the display device 2 was A or B, and it is more preferable to be A.
A: screen was displayed in black and coloring was not visually recognized.
B: red coloration was slightly visible, which is acceptable.
C: red coloration was clearly visible, which is not acceptable.

### [Durability]

A display device having a favorable evaluation of the black density among the display device 1 and the display device 2 was allowed to age for 500 hours in an environment of 80° C. and a relative humidity of less than 10%. Thereafter, the display screen of the produced organic EL display device was set to black display, and reflected light in a case where a fluorescent lamp was projected from the front was observed. Durability was evaluated based on the following standard. Practically, A or B is preferable, and A is more preferable.
A: screen was displayed in black and coloring was not visually recognized.
B: coloration was slightly visible, which is acceptable.
C: coloration was clearly visible, which is not acceptable.

TABLE 1

| | Light absorption anisotropic film | | | | | | | | | | | |
|---|---|---|---|---|---|---|---|---|---|---|---|---|
| | | Liquid | Unevenly | | Arrangement structure | | | | | Black density | | |
| | Dichroic | crystal | distributed | | | | | Ltop/ | Llow/ | Display | Display | |
| | substance | compound | substance | Process | Ltop | Llow | Lmid | Lmid | Lmid | device 1 | device 2 | Durability |
| Example 1 | C1, M1, Y1 | L-1, L-2 | PEO | | 28 | 64 | 62 | 0.45 | 1.03 | A | C | A |
| | | | Mw = 100,000 | | | | | | | | | |
| Example 2 | C1, M1, Y1 | L-1, L-2 | EPICLON N-695 | | 62 | 27 | 61 | 1.02 | 0.44 | C | A | A |
| | | | 2 wt % | | | | | | | | | |
| Example 3 | C1, M1, Y1 | L-1, L-2 | PEO + | | 28 | 26 | 60 | 0.47 | 0.43 | A | A | A |
| | | | EPICLON | | | | | | | | | |
| | | | 2 wt % + 2 wt % | | | | | | | | | |
| Example 4 | C1, M1, Y1 | L-1, L-2 | None | Atmospheric | 59 | 25 | 59 | 1.00 | 0.42 | C | A | A |
| | | | | exposure | | | | | | | | |
| Example 5 | C1, M1, Y1 | L-1, L-2 | None | Atmospheric | 46 | 28 | 30 | 1.53 | 0.93 | C | A | C |
| | | | | exposure | | | | | | | | |
| | | | | strongly | | | | | | | | |
| Example 6 | C1, M1, Y1 | L-1, L-2 | None | Short-wavelength | 23 | 58 | 55 | 0.42 | 1.05 | A | C | A |
| | | | | UV exposure | | | | | | | | |
| Example 7 | C1, M1, Y1 | L-1, L-2 | None | Short-wavelength | 34 | 56 | 56 | 0.61 | 1.00 | B | C | A |
| | | | | UV exposure | | | | | | | | |
| | | | | weakly | | | | | | | | |
| Example 8 | C1, C2, M1, | L-1, L-2 | None | Atmospheric | 58 | 24 | 59 | 0.98 | 0.41 | C | A | A |
| | Y1 | | | exposure | | | | | | | | |
| Example 9 | C1, C2, M1, | L-1, L-2 | None | Short-wavelength | 25 | 59 | 59 | 0.42 | 1.00 | A | C | A |
| | Y1 | | | UV exposure | | | | | | | | |
| Example 10 | C1, C2, M1, | L-1, L-2 | None | Atmospheric | 55 | 21 | 54 | 1.02 | 0.39 | C | A | A |
| | Y2 | | | exposure | | | | | | | | |
| Example 11 | C1, C2, M1, | L-1, L-2 | None | Short-wavelength | 22 | 55 | 56 | 0.39 | 0.98 | A | C | A |
| | Y2 | | | UV exposure | | | | | | | | |
| Example 12 | C1, C2, M1, | L-3, L-4 | None | Short-wavelength | 29 | 60 | 61 | 0.48 | 0.98 | A | C | A |
| | Y2 | | | UV exposure | | | | | | | | |
| Comparative | C1, M1, Y1 | L-1, L-2 | None | | 64 | 65 | 66 | 0.97 | 0.98 | C | C | |
| Example 1 | | | | | | | | | | | | |

As can be seen from Table 1, all of Examples 1 to 12, satisfying at least one of the expression (1-1) or the expression (1-2), exhibited excellent black density.

In addition, from the comparison of Examples 1 to 12, Examples 1 to 4 and Examples 6 to 12, satisfying the expression (3-1), exhibited excellent durability.

In addition, from the comparison of Examples 1 to 12, Examples 1 to 6 and Examples 8 to 12, in which at least one of Ltop or Llow was 30 nm or less, exhibited more excellent black density.

On the other hand, in Comparative Example 1 in which neither of the expression (1-1) and the expression (1-2) was satisfied, the black density was insufficient.

### EXPLANATION OF REFERENCES

a: one surface
b: other surface
c: center in film thickness direction
A: region A
B: region B
C: region C
100: light absorption anisotropic film

What is claimed is:

1. Alight absorption anisotropic film comprising:
a dichroic substance; and
a liquid crystal compound,
wherein at least a part of the dichroic substance forms an arrangement structure, and
in a cross section observed with a scanning transmission electron microscope, in a case where an average value of lengths of major axes of arrangement structures observed in a region A from one surface to 150 nm in a film thickness direction is denoted by Ltop and an average value of lengths of major axes of arrangement structures in a region B from the other surface to 150 nm in the film thickness direction is denoted by Llow, at least one of the following expression (1-1) or expression (1-2) is satisfied,
$$Ltop \leq 35 nm , \qquad ( 1 - 1 )$$
$$Llow \leq 35 nm . \qquad ( 1 - 2 )$$

2. The light absorption anisotropic film according to claim 1,
wherein, in the cross section observed with the scanning transmission electron microscope, in a case where an average value of lengths of major axes of arrangement structures in a region C of 150 nm from a center in the film thickness direction is denoted by Lmid, at least one of the following expression (2-1) or expression (2-2) is satisfied,
$$Ltop / Lmid < 0.87 , \qquad ( 2 - 1 )$$
$$Llow / Lmid < 0.87 . \qquad ( 2 - 2 )$$

3. The light absorption anisotropic film according to claim 1,
wherein, in the cross section observed with the scanning transmission electron microscope, in a case where an average value of lengths of major axes of arrangement structures in a region C of 150 nm from a center in the film thickness direction is denoted by Lmid, the following expression (3-1) is satisfied,
$$Lmid > 40 nm . \qquad ( 3 - 1 )$$

4. The light absorption anisotropic film according to claim 1, further comprising:
an unevenly distributed substance which is unevenly distributed in at least one of the region A or the region B.

5. The light absorption anisotropic film according to claim 4,
wherein a weight-average molecular weight of the unevenly distributed substance is 1000 or more.

6. A manufacturing method of the light absorption anisotropic film according to claim 1, the manufacturing method comprising:
a coating film-forming step of forming a coating film by applying a composition for forming a light absorption anisotropic film, containing a dichroic substance and a liquid crystal compound, onto an alignment film; and
an alignment step of aligning the dichroic substance contained in the coating film to obtain the light absorption anisotropic film.

7. The manufacturing method according to claim 6,
wherein the alignment step includes a step of exposing the coating film to light in an atmosphere.

8. The manufacturing method according to claim 6,
wherein the alignment step includes a step of exposing the coating film to ultraviolet rays which do not include light of 330 nm or more.

9. A laminate comprising:
the light absorption anisotropic film according to claim 1; and
a λ/4 plate.

10. An image display device comprising:
the light absorption anisotropic film according to claim 1.

11. The light absorption anisotropic film according to claim 2,
wherein the following expression (3-1) is satisfied,
$$Lmid > 40 nm . \qquad ( 3 - 1 )$$

12. The light absorption anisotropic film according to claim 2, further comprising:
an unevenly distributed substance which is unevenly distributed in at least one of the region A or the region B.

13. The light absorption anisotropic film according to claim 11,
wherein a weight-average molecular weight of the unevenly distributed substance is 1000 or more.

14. A manufacturing method of the light absorption anisotropic film according to claim 2, the manufacturing method comprising:
a coating film-forming step of forming a coating film by applying a composition for forming a light absorption anisotropic film, containing a dichroic substance and a liquid crystal compound, onto an alignment film; and
an alignment step of aligning the dichroic substance contained in the coating film to obtain the light absorption anisotropic film.

15. The manufacturing method according to claim 14,
wherein the alignment step includes a step of exposing the coating film to light in an atmosphere.

16. The manufacturing method according to claim 14,
wherein the alignment step includes a step of exposing the coating film to ultraviolet rays which do not include light of 330 nm or more.

17. A laminate comprising:
the light absorption anisotropic film according to claim 2; and
a λ/4 plate.

18. An image display device comprising:
the light absorption anisotropic film according to claim 2.

19. The light absorption anisotropic film according to claim 3, further comprising:
an unevenly distributed substance which is unevenly distributed in at least one of the region A or the region B.

20. The light absorption anisotropic film according to claim 19,
wherein a weight-average molecular weight of the unevenly distributed substance is 1000 or more.
